(19) United States
(12) Patent Application Publication
(10) Pub. No.: US 2025/0373334 A1
(43) Pub. Date: Dec. 4, 2025

(54) OPTICAL MODULE AND METHOD OF CONTROLLING OPTICAL MODULE

(71) Applicant: Mitsubishi Electric Corporation, Tokyo (JP)

(72) Inventor: Junichi SUZUKI, Tokyo (JP)

(73) Assignee: Mitsubishi Electric Corporation, Tokyo (JP)

(21) Appl. No.: 19/306,429

(22) Filed: Aug. 21, 2025

Related U.S. Application Data
(63) Continuation of application No. PCT/JP2023/015702, filed on Apr. 20, 2023.

(51) Int. Cl. H04B 10/079

(52) U.S. Cl. CPC H04B 10/07957

(57) ABSTRACT

An optical module includes a semiconductor laser and an optical monitor to receive a laser beam from the semiconductor laser and output a first monitor value and a second monitor value for estimating intensity and a wavelength of the laser beam from the semiconductor laser. An optical monitor constitutes an optical interferometer including a first optical coupler to receive a laser beam from the semiconductor laser, a second optical coupler to receive the laser beam from the semiconductor laser, a first optical receiver to output the first monitor value, and a second optical receiver to output the second monitor value, and a first path from the first optical coupler to the first optical receiver and a second path from the second optical coupler to the second optical receiver are asymmetric.

### CROSS REFERENCE TO RELATED APPLICATION

This application is a Continuation of PCT International Application No. PCT/JP2023/015702, filed on Apr. 20, 2023, which is hereby expressly incorporated by reference into the present application.

### TECHNICAL FIELD

The present disclosure relates to an optical module and a method of controlling the optical module, and particularly relates to an optical module including a single-wavelength semiconductor laser and a method of controlling the optical module.

### BACKGROUND ART

As a method for increasing the capacity of an optical communication system, there is a digital coherent communication method. The digital coherent communication method is a method of transmitting a large number of channels by placing a signal not only on the intensity of light but also on the phase. An interference phenomenon of light is used to extract phase information of light, and thus it is necessary to precisely control wavelengths of both a light source of a transmitter that transmits a signal and local light that is interference light in a receiver that receives the signal.

A single mode laser is used as these light sources.

The single mode laser oscillates at a single wavelength, but changes in oscillation wavelength and optical output intensity due to manufacturing errors and environmental temperatures.

Accordingly, a wavelength locker for wavelength control and a light intensity monitor are necessary in a light source module for digital coherent communication equipped with a single mode laser.

Patent Literature 1 discloses a laser module that locks a wavelength of a laser within a desired range.

The laser module disclosed in Patent Literature 1 compares a monitor output of a light receiving element that monitors light emitted from a rear end surface of a laser through a lens and a beam splitter with a monitor output of a light receiving element that has monitored light passing through an etalon, and locks a wavelength of the laser in a desired range by controlling temperatures of a first Peltier element and a second Peltier element.

In the laser module disclosed in Patent Literature 1, a laser, a third condenser lens, a first condenser lens, a beam splitter, two light receiving elements, and a thermistor are mounted on a mounting surface of a first Peltier element, and an etalon is mounted on a mounting surface of a second Peltier element.

### CITATION LIST

### Patent Literatures

Patent Literature 1: JP 2003-69130 A

### SUMMARY OF INVENTION

### Technical Problem

In the laser module disclosed in Patent Literature 1, a Peltier element is provided in each of the laser and the etalon, and the number of components is large.

In addition, since the etalon is used, a component for collimating light incident on the etalon is required, and the size of the etalon itself is also required to some extent.

The present disclosure has been made in view of the above points, and an object of the present disclosure is to obtain an optical module that emits a single wavelength, and that has a small number of components and can be downsized.

### Solution to Problem

An optical module according to the present disclosure includes a semiconductor laser and an optical monitor to receive a laser beam from the semiconductor laser and output a first monitor value and a second monitor value for estimating intensity and a wavelength of the laser beam from the semiconductor laser. The optical monitor includes an optical monitor constituting an optical interferometer including a first optical coupler to receive the laser beam from the semiconductor laser, a second optical coupler to receive the laser beam from the semiconductor laser, a first optical receiver to output the first monitor value, and a second optical receiver to output the second monitor value, and a first path from the first optical coupler to the first optical receiver and a second path from the second optical coupler to the second optical receiver are asymmetric.

### Advantageous Effects of Invention

According to the present disclosure, precise control can be performed for a single wavelength, the number of parts is small, and downsizing can be achieved.

### BRIEF DESCRIPTION OF DRAWINGS

FIG. 1 is a perspective view illustrating a state in which a cap is removed from an optical module according to a first embodiment.

FIG. 2 is a perspective view illustrating the optical module according to the first embodiment.

FIG. 3 is a cross-sectional view taken along line III-III of FIG. 1.

FIG. 4 is a block diagram illustrating an optical monitor in the optical module according to the first embodiment.

FIG. 5 is a schematic perspective view illustrating the optical monitor in the optical module according to the first embodiment.

FIG. 6 is a schematic block diagram illustrating the optical module device according to the first embodiment.

FIG. 7 is a diagram illustrating an output obtained by the optical monitor in the optical module device according to the first embodiment.

FIG. 8 is a diagram illustrating an optical power monitor value Ip that is a total value of a first monitor value and a second monitor value, and a wavelength monitor value Iλ that is a difference value between the first monitor value and the second monitor value obtained by the optical monitor in the optical module device according to the first embodiment.

FIG. 9 is a flowchart illustrating an operation in the optical module according to the first embodiment.

FIG. 10 is a view illustrating a state where a backward laser beam of the semiconductor laser deviates from a first optical coupler and a second optical coupler in the optical module according to the first embodiment.

FIG. 11 is a diagram illustrating an equiphase surface in a state where the backward laser beam of the semiconductor laser deviates from the first optical coupler and the second optical coupler in the optical module according to the first embodiment.

FIG. 12 is a diagram illustrating a result of trial calculation of a mounting deviation and a coupling gradient in the optical module according to the first embodiment.

FIG. 13 is a schematic perspective view illustrating an optical monitor in an optical module according to a second embodiment.

FIG. 14 is a diagram illustrating an output obtained by the optical monitor in the optical module according to the second embodiment.

FIG. 15 is a schematic perspective view illustrating an optical monitor in an optical module according to the third embodiment.

FIG. 16 is a diagram illustrating a waveform of an I photocurrent and, a waveform of a Q photocurrent, and a relationship between a waveform of an I photocurrent, the Q photocurrent, an optical power monitor value Ip, and a wavelength monitor value Iλ in the optical module according to the third embodiment.

### DESCRIPTION OF EMBODIMENTS

### First Embodiment

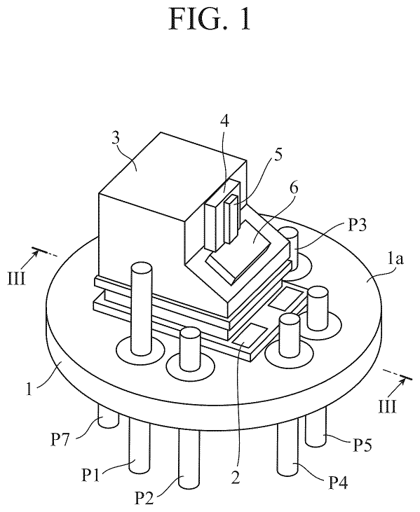

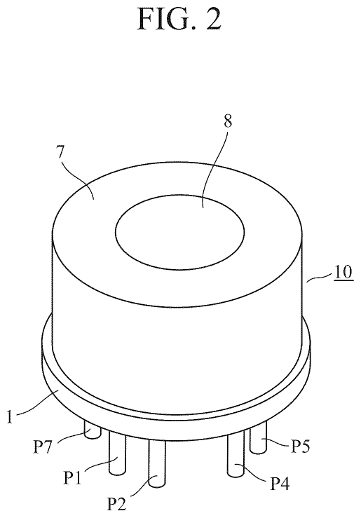

An optical module according to a first embodiment will be described with reference to FIGS. 1 to 12.

The optical module according to the first embodiment is preferable for use as a light source module for digital coherent communication.

The optical module according to the first embodiment is an example applied to a TO-CAN type optical transmission module for optical communication.

The optical module according to the first embodiment is an optical module including a single-wavelength semiconductor laser.

The optical module according to the first embodiment is an optical module having a function of adjusting the temperature of the semiconductor laser and a function of monitoring an optical output from the semiconductor laser and monitoring an oscillation wavelength.

Therefore, a TO-CAN type optical transmission module for optical communication will be described below as an example.

As illustrated in FIGS. 1 to 3, the optical module according to the first embodiment includes a stem 1, a temperature adjuster 2, a base 3, a semiconductor laser submount (hereinafter, it is abbreviated as a submount) 4, a semiconductor laser 5, a planar waveguide optical monitor (hereinafter, it is abbreviated as an optical monitor) 6, a cap 7, a plurality of lead pins P1 to P6, and a grounding lead pin P7.

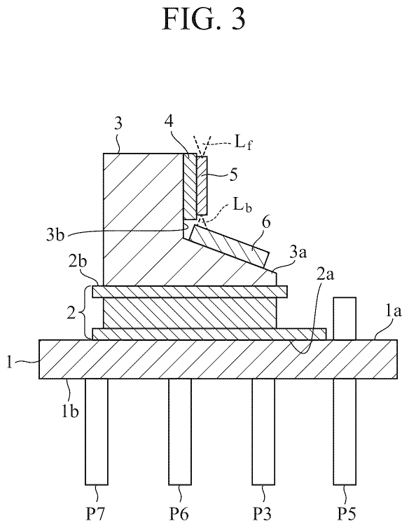

In FIGS. 1 and 3, wires for electrically and optically connecting the components 2, 5, and 6 and the lead pins P1 to P6 are omitted in order to avoid complexity.

The stem 1 is formed by a disk-shaped metal. Note that the stem 1 is not limited to the disk shape, and may have a columnar shape or a quadrangular prismatic shape, and is only required to be a flat plate shape having an inner flat surface la and an outer flat surface 1b parallel to the inner flat surface 1a.

The inner flat surface 1a of the stem 1 is a mounting surface and is a region for component mounting.

In the present example, the stem 1 is a disk-shaped metal having a diameter of 5.6 mm.

The stem 1 is combined with the cap 7 to form the package 10. The package 10 is a TO-CAN type package.

The cap 7 is a windowed cap having a bottomed portion and a side wall portion with one end opened.

The cap 7 is a lens cap made by metal and formed by cylindrical metal having an outer diameter slightly smaller than a diameter of the stem 1.

At the center of the bottomed portion of the cap 7, an opening on which flat glass or a lens as a window 8 is mounted is formed.

The flat glass or lens that is the window 8 is attached to an opening formed in the bottomed portion by bonding with an adhesive or melting in such a manner that airtightness is maintained inside and outside the cap.

An end surface of the side wall portion of the cap 7 comes into contact with the peripheral end portion of the inner flat surface 1a of the stem 1 and is joined and fixed by electric welding.

The inside surrounded by the stem 1 and the cap 7 is filled with an inert gas or brought into a vacuum state, and is hermetically sealed by blocking the semiconductor laser 5 from the outside air.

Forward laser beam Lf from the semiconductor laser 5 is emitted from the window 8.

The temperature adjuster 2 is housed in the package 10 and placed on the stem 1.

The temperature adjuster 2 has a lower surface 2a that is a flat surface and an upper surface 2b that is a flat surface parallel to the lower surface 2a, the lower surface 2a is fixed to the inner flat surface 1a of the stem 1 with solder or a conductive adhesive, and the upper surface 2b serves as a mounting surface. Hereinafter, the upper surface 2b is referred to as a mounting surface.

The temperature adjuster 2 heats or cools the mounting surface 2b by a photocurrent flowing therethrough.

When a monitor value from the optical monitor 6 deviates from a set monitor value, the temperature adjuster 2 performs control to change the temperature applied to the semiconductor laser 5 and the optical monitor 6.

The temperature adjuster 2 adjusts the temperature of the semiconductor laser 5 and the temperature of the optical monitor 6.

The temperature adjuster 2 is a thermo-electric cooler (TEC) including a Peltier element.

The base 3 is an L-shaped metal member that is mounted on the mounting surface 2b of the temperature adjuster 2 and includes a flat surface portion 3a having upper and lower surfaces that are flat surfaces, and an elevation surface portion 3b formed integrally with the flat surface portion 3a and having an elevation surface that is a flat surface.

The lower surface of the flat surface portion 3a of the base 3 is fixed to the mounting surface 2b of the temperature adjuster 2 with solder or a conductive adhesive.

The semiconductor laser 5 is mounted and fixed on the elevation surface of the elevation surface portion 3b of the base 3 via the semiconductor laser submount 4.

The semiconductor laser 5 is fixed to the elevation surface of the elevation surface portion 3b of the base 3 in such a manner that an optical axis of a forward laser beam Lf and an optical axis of a backward laser beam Lb of the semiconductor laser 5 coincide with a central axis of the stem 1.

The submount 4 includes, for example, a substrate formed by a dielectric of aluminum nitride (AlN) having a metal wiring layer patterned on the surface.

The optical monitor 6 is mounted and fixed on an upper surface of the flat surface portion 3a of the base 3.

The optical monitor 6 is fixed to the upper surface of the flat surface portion 3a of the base 3 so as to receive the backward laser beam Lb of the semiconductor laser 5.

The optical monitor 6 is disposed at an angle at which the backward laser beam Lb of the semiconductor laser 5 can be received.

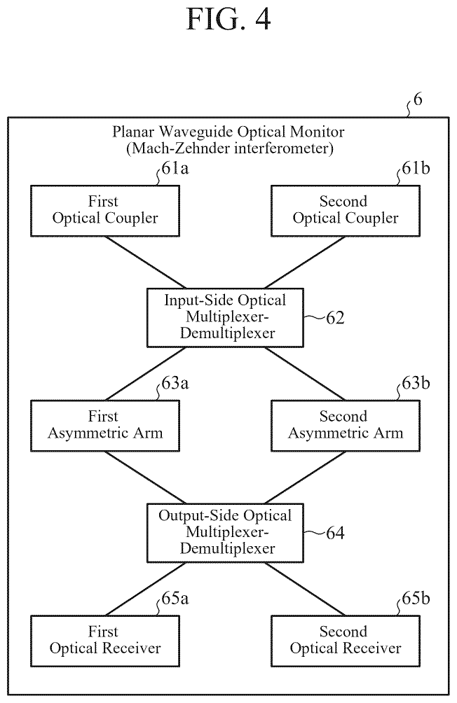

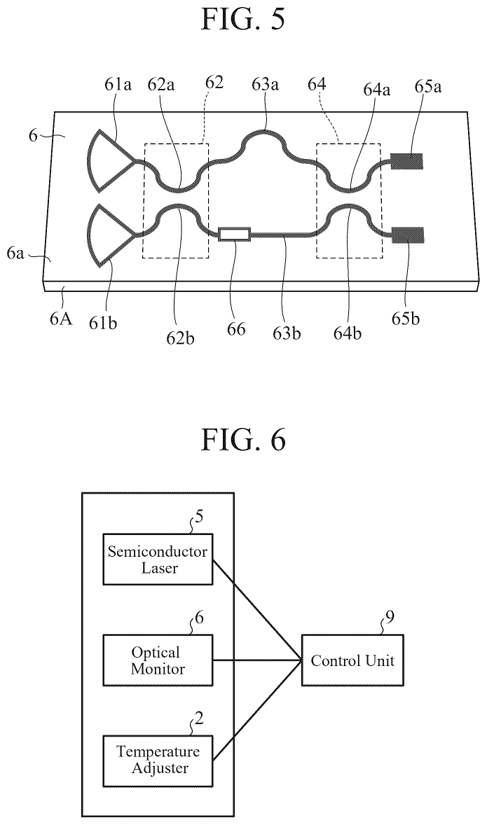

That is, the optical monitor 6 and the semiconductor laser 5 are arranged at an angle at which the maximum coupling efficiency of a first optical coupler 61a and a second optical coupler 61b (see FIGS. 4 and 5) in the optical monitor 6 with respect to the backward laser beam Lb of the semiconductor laser 5 can be obtained.

For example, the backward laser beam Lb of the semiconductor laser 5 is arranged so as to hit the first optical coupler 61a and the second optical coupler 61b of the optical monitor 6 substantially perpendicularly.

In this example, in the base 3, the base 3 is manufactured in such a manner that the upper surface of the flat surface portion 3a and the surface of the elevation surface portion 3b, that is, the placement surface of the submount 4 has an inclination. An internal angle, which is an angle formed between the upper surface of the flat surface portion 3a and the surface of the elevation surface portion 3b, is inclined at an angle exceeding 90 degrees, and the semiconductor laser 5 and the optical monitor 6 are arranged on the base 3 at an angle.

As described above, by setting the internal angle, which is the angle formed between the upper surface of the flat surface portion 3a and the surface of the elevation surface portion 3b, not to be completely perpendicular but to be shifted from 90 degrees, it is possible to suppress reflected return light of the backward laser beam Lb of the semiconductor laser 5 reflected from the first optical coupler 61a and the second optical coupler 61b in the optical monitor 6 from being incident on the semiconductor laser 5.

As a result, unstable laser operation in the semiconductor laser 5 can be avoided.

The base 3 conducts heat on the mounting surface 2b of the temperature adjuster 2 to adjust the temperature of the semiconductor laser 5 through the submount 4, that is, to heat or cool the semiconductor laser 5.

At the same time, the base 3 conducts heat on the mounting surface 2b of the temperature adjuster 2 to adjust the temperature of the optical monitor 6, that is, to heat or cool the optical monitor 6.

Since the semiconductor laser 5 whose temperature is adjusted by the temperature adjuster 2 and the optical monitor 6 are disposed in a vertical direction by the base 3, the area occupied by the semiconductor laser 5 and the optical monitor 6 on the mounting surface 2b of the temperature adjuster 2 can be reduced, and as a result, the temperature adjuster 2 can be downsized, and the optical module can be downsized.

The semiconductor laser 5 is a single-wavelength semiconductor laser, that is, a single mode laser oscillating at a single wavelength. As the single-wavelength semiconductor laser, for example, a distributed feedback (DFB) laser diode element (chip) or a distributed Bragg reflector (DBR) laser diode element (chip) is used.

The semiconductor laser 5 emits the forward laser beam Lf from the emission surface, and emits the backward laser beam Lb from the rear surface. The forward laser beam Lf is used for optical communication, and the backward laser beam Lb is monitored.

In this type of single-wavelength semiconductor laser, the light intensity changes depending on the supplied driving photocurrent, the light intensity also changes depending on the temperature of the semiconductor laser itself, and the light output generally increases as the temperature is lower.

Furthermore, an oscillation wavelength of the laser beam from the single-wavelength semiconductor laser also changes due to the temperature in the laser. The oscillation wavelength of the laser beam from the single-wavelength semiconductor laser also changes due to Joule heat caused by the driving photocurrent.

Therefore, in the first embodiment, the backward laser beam Lb from the semiconductor laser 5 is monitored by the optical monitor 6, and the temperature of the semiconductor laser 5 is adjusted by the temperature adjuster 2 to keep the wavelength of the laser beam oscillated from the semiconductor laser 5 constant.

The optical monitor 6 outputs, to a control unit 9 (see FIG. 6) that controls the temperature adjuster 2, a monitor value for causing the temperature adjuster 2 to perform control to change the temperature given to the semiconductor laser 5 and the optical monitor 6.

The control unit 9 controls the temperature adjuster 2, the semiconductor laser 5, and the optical monitor 6. The control unit 9 exchanges signals with the semiconductor laser 5, the optical monitor 6, and the temperature adjuster 2, and controls the photocurrent and voltage to each of the semiconductor laser 5, the optical monitor 6, and the temperature adjuster 2 to control the light intensity of the laser beam from the semiconductor laser 5 and the wavelength of the laser beam.

The optical monitor 6 measures the light intensity of the backward laser beam Lb from the semiconductor laser 5, and outputs a first monitor value and a second monitor value for estimating the intensity and wavelength of the forward laser beam Lf from the semiconductor laser 5.

The optical monitor 6 includes a first optical coupler 61a that receives the backward laser beam Lb from the semiconductor laser 5, a second optical coupler 61b that receives the backward laser beam Lb from the semiconductor laser 5, a first optical receiver 65a that outputs the first monitor value, and a second optical receiver 65b that outputs the second monitor value, and constitutes an optical interferometer in which a first path from the first optical coupler 61a to the first optical receiver 65a and a second path from the second optical coupler 61b to the second optical receiver 65b are asymmetric. The optical interferometer is, for example, a Mach-Zehnder interferometer.

The sum of the first monitor value and the second monitor value is an optical power monitor value Ip including a photocurrent value for controlling the value of the driving photocurrent to the semiconductor laser 5 in such a manner that the optical output of the semiconductor laser 5 becomes a target value.

A difference value between the first monitor value and the second monitor value is a wavelength monitor value Iλ including a photocurrent value used to control a value of photocurrent supplied to the temperature adjuster 2 in such a manner that the wavelength of the laser beam from the semiconductor laser 5 becomes a target value.

The optical monitor 6 constitutes a part of a wavelength locker for wavelength control of laser beam from the semiconductor laser 5.

The temperature adjuster 2 performs control to heat the mounting surface 2b in accordance with the value of the photocurrent to be supplied to increase the temperature to be given to the semiconductor laser 5 and the optical monitor 6 when the optical power monitor value Ip is larger than a photocurrent set value, and cool the mounting surface 2b in accordance with the value of the photocurrent to be supplied to decrease the temperature to be given to the semiconductor laser 5 and the optical monitor 6 when the optical power monitor value Ip is smaller than the photocurrent set value.

The photocurrent set value is set to, for example, ±10% of a target value Ip_target of the optical power monitor value Ip when the optical output of the semiconductor laser 5, that is, the driving photocurrent at which the light intensity becomes the target value is supplied to the semiconductor laser 5.

When a wavelength monitor value Iλ/Ip, which is a ratio between the optical power monitor value Ip and the wavelength monitor value Iλ, deviates from a wavelength set value, the temperature adjuster 2 changes the temperature of the mounting surface 2b in accordance with the value of the supplied photocurrent, and changes the temperature to be given to the semiconductor laser 5 and the optical monitor 6.

In the present example, the temperature adjuster 2 performs control to heat the mounting surface 2b in accordance with the value of the photocurrent to be supplied to increase the temperature to be given to the semiconductor laser 5 and the optical monitor 6 when the wavelength monitor value Iλ/Ip is larger than the wavelength set value, and cool the mounting surface 2b in accordance with the value of the photocurrent to be supplied to decrease the temperature to be given to the semiconductor laser 5 and the optical monitor 6 when the wavelength monitor value Iλ/Ip is smaller than the wavelength set value.

For example, the wavelength set value is set to ±10% of the target value Iλ_target of the wavelength monitor value Iλ/Ip when the wavelength λLD of the laser beam of the semiconductor laser 5 is set to the target value λ_target.

As illustrated in FIGS. 4 and 5, the optical monitor 6 includes a first optical coupler 61a, a second optical coupler 61b, an input-side optical multiplexer-demultiplexer 62, a first asymmetric arm 63a, a second asymmetric arm 63b, an output-side optical multiplexer-demultiplexer 64, a first optical receiver 65a, a second optical receiver 65b, and a phase adjuster 66.

The output-side optical multiplexer-demultiplexer 64, the first optical receiver 65a, and the second optical receiver 65b function as an interference measurement system for viewing wavelength dependence.

The output-side optical multiplexer-demultiplexer 64 is an optical circuit constituting an interference measurement system by the first optical receiver 65a and the second optical receiver 65b.

The optical monitor 6 is, for example, a planar waveguide optical monitor using a silicon photonics chip formed by integrating the first optical coupler 61a, the second optical coupler 61b, the input-side optical multiplexer-demultiplexer 62, the first asymmetric arm 63a, the second asymmetric arm 63b, the output-side optical multiplexer-demultiplexer 64, the first optical receiver 65a, and the second optical receiver 65b on a flat surface of a silicon (Si) substrate 6A.

The phase adjuster 66 is located over a portion of the second asymmetric arm 63b and is formed on an insulating film (not illustrated) formed on a surface of the silicon photonics chip.

The first optical coupler 61a receives the backward laser beam Lb from the semiconductor laser 5, and couples the backward laser beam Lb incident perpendicularly to the flat surface 6a of the optical monitor 6 to the first optical waveguide 62a constituting the input-side optical multiplexer-demultiplexer 62.

The second optical coupler 61b receives the backward laser beam Lb from the semiconductor laser 5, and couples the backward laser beam Lb incident perpendicularly to the flat surface 6a of the optical monitor 6 to the second optical waveguide 62b constituting the input-side optical multiplexer-demultiplexer 62.

Each of the first optical coupler 61a and the second optical coupler 61b is, for example, a grating coupler. Since the grating coupler has a function of coupling the backward laser beam Lb from the semiconductor laser 5 coming from above the flat surface 6a of the optical monitor 6 to each of the first optical waveguide 62a and the second optical waveguide 62b constituting the input-side optical multiplexer-demultiplexer 62, the flat surface 6a of the optical monitor 6 and the semiconductor laser 5 are arranged by the base 3 at an angle at which the maximum coupling efficiency of the grating coupler can be obtained.

Note that the optical coupler 61 may be an elephant coupler.

The grating coupler can increase the mode of light and hence has a feature of having smaller position dependence than that of end surface coupling of waveguides, and thus the grating coupler is preferable for the first optical coupler 61a and the second optical coupler 61b of this example.

The input-side optical multiplexer-demultiplexer 62 is a 2×2 optical multiplexer-demultiplexer having a first port to a fourth port and having the first optical waveguide 62a connecting the first port and the second port and the second optical waveguide 62b connecting the third port and the fourth port.

In the input-side optical multiplexer-demultiplexer 62, a first port is coupled with the first optical coupler 61a, and a third port is coupled with the second optical coupler 61b.

The input-side optical multiplexer-demultiplexer 62 is an asymmetric optical multiplexer-demultiplexer, and in this example, a power branch ratio is set to 0.8, for example. In other words, the power branch ratio for the first optical waveguide 62a and the second optical waveguide 62b is 2:8.

Note that the asymmetric optical multiplexer-demultiplexer is an optical multiplexer-demultiplexer having a power branch ratio of a value obtained by changing the power branch ratio from 0.5.

One feature of the optical module according to the first embodiment is that an asymmetric optical multiplexer-demultiplexer is used as the input-side optical multiplexer-demultiplexer 62.

Each of the first optical waveguide 62a and the second optical waveguide 62b constituting the input-side optical multiplexer-demultiplexer 62 is a silicon waveguide formed of silicon in a case where the optical monitor 6 is constituted by a planar waveguide optical monitor using a silicon photonics chip.

The length of first optical waveguide 62a and the length of second optical waveguide 62b are the same.

As the input-side optical multiplexer-demultiplexer 62, for example, either a directional coupler or a multi-mode interference waveguide (multi-mode interferometer (MMI)) having a first port to a fourth port and having a propagation path of light from the first port to the second port and a propagation path of light from the third port to the fourth port can be used.

In this example, the propagation path of light from the first port to the second port is referred to as the first optical waveguide 62a, and the propagation path of light from the third port to the fourth port is referred to as the second optical waveguide 62b.

An input node of the first asymmetric arm 63a is optically connected to the second port of the input-side optical multiplexer-demultiplexer 62.

The first asymmetric arm 63a is a silicon waveguide formed of silicon in a case where the optical monitor 6 is constituted by a planar waveguide optical monitor using a silicon photonics chip.

Note that the second port of the input-side optical multiplexer-demultiplexer 62 and the input node of the first asymmetric arm 63a are not physically configured separately, but are a connection point of silicon waveguides continuously forming the first optical waveguide 62a and the first asymmetric arm 63a constituting the input-side optical multiplexer-demultiplexer 62.

An input node of the second asymmetric arm 63b is optically connected to the fourth port of the input-side optical multiplexer-demultiplexer 62.

The second asymmetric arm 63b is a silicon waveguide formed of silicon in a case where the optical monitor 6 is constituted by a planar waveguide optical monitor using a silicon photonics chip.

Note that the fourth port of the input-side optical multiplexer-demultiplexer 62 and the input node of the second asymmetric arm 63b are not physically configured separately, but are a connection point of silicon waveguides continuously forming the first optical waveguide 62a and the second asymmetric arm 63b constituting the input-side optical multiplexer-demultiplexer 62.

The length of the optical waveguide in the first asymmetric arm 63a is longer than the length of the optical waveguide in the second asymmetric arm 63b by a length ΔL.

Since the length of the optical waveguide in the first asymmetric arm 63a is different from the length of the optical waveguide in the second asymmetric arm 63b, light propagating through the first asymmetric arm 63a and light propagating through the second asymmetric arm 63b are obtained with phases shifted from each other due to their inverse phase relationship.

The output-side optical multiplexer-demultiplexer 64 is a 2×2 optical multiplexer-demultiplexer having a first port to a fourth port and having a third optical waveguide 64a connecting the first port and the second port and a fourth optical waveguide 64b connecting the third port and the fourth port.

In the output-side optical multiplexer-demultiplexer 64, a first port is a first input node of the optical circuit constituting the interference measurement system, a second port is a first output node of the optical circuit constituting the interference measurement system, a third port is a second input node of the optical circuit constituting the interference measurement system, and a fourth port is a second output node of the optical circuit constituting the interference measurement system.

In the output-side optical multiplexer-demultiplexer 64, the first port is optically connected to an output node of the first asymmetric arm 63a, and the third port is optically connected to an output node of the second asymmetric arm 63b.

The output-side optical multiplexer-demultiplexer 64 is an asymmetric optical multiplexer-demultiplexer, and in this example, the power branch ratio is set to 0.8, for example. In other words, the power branch ratio for the third optical waveguide 64a and the fourth optical waveguide 64b is 2:8.

Note that the asymmetric optical multiplexer-demultiplexer is an optical multiplexer-demultiplexer having a power branch ratio of a value obtained by changing the power branch ratio from 0.5.

One feature of the optical module according to the first embodiment is that an asymmetric optical multiplexer-demultiplexer is used as the output-side optical multiplexer-demultiplexer 64.

Each of the third optical waveguide 64a and the fourth optical waveguide 64b constituting the output-side optical multiplexer-demultiplexer 64 is a silicon waveguide formed of silicon in a case where the optical monitor 6 is constituted by a planar waveguide optical monitor using a silicon photonics chip.

The length of third optical waveguide 64a and the length of fourth optical waveguide 64b are the same.

Note that the first port of the output-side optical multiplexer-demultiplexer 64 and the output node of the first asymmetric arm 63a are not physically configured separately, but are a connection point of silicon waveguides continuously forming the third optical waveguide 64a and the first asymmetric arm 63a constituting the output-side optical multiplexer-demultiplexer 64.

Note that the third port of the output-side optical multiplexer-demultiplexer 64 and the output node of the second asymmetric arm 63b are not physically configured separately, but are a connection point of silicon waveguides continuously forming the fourth optical waveguide 64b and the second asymmetric arm 63b constituting the output-side optical multiplexer-demultiplexer 64.

As the output-side optical multiplexer-demultiplexer 64, for example, either a directional coupler or an MMI waveguide having a first port to a fourth port and having a propagation path of light from the first port to the second port and a propagation path of light from the third port to the fourth port can be used.

In this example, the propagation path of light from the first port to the second port is referred to as a third optical waveguide 64a, and the propagation path of light from the third port to the fourth port is referred to as a fourth optical waveguide 64b.

The input-side optical multiplexer-demultiplexer 62, the first asymmetric arm 63a, the second asymmetric arm 63b, and the output-side optical multiplexer-demultiplexer 64 constitute a so-called optical interferometer.

The first optical receiver 65a receives light from the second port of the output-side optical multiplexer-demultiplexer 64, photoelectrically converts the light, and outputs a first monitor value including a photocurrent.

The first optical receiver 65a is a waveguide optical receiver or a surface incident optical receiver, and in this example, a photodiode which is a silicon germanium (SiGe) optical receiver is used.

The second optical receiver 65b receives light from the fourth port of the output-side optical multiplexer-demultiplexer 64, photoelectrically converts the light, and outputs a second monitor value including a photocurrent.

The second optical receiver 65b is a waveguide optical receiver or a surface incident optical receiver, and in this example, a photodiode which is a SiGe optical receiver is used.

The first path is a propagation path of light by a silicon waveguide from the first port of the input-side optical multiplexer-demultiplexer 62 to the second port of the output-side optical multiplexer-demultiplexer 64 via the input-side optical multiplexer-demultiplexer 62, the first asymmetric arm 63a, and the output-side optical multiplexer-demultiplexer 64 in a case where the optical monitor 6 is constituted by a planar waveguide optical monitor using a silicon photonics chip.

The second path is a propagation path of light by a silicon waveguide from the third port of the input-side optical multiplexer-demultiplexer 62 to the fourth port of the output-side optical multiplexer-demultiplexer 64 via the input-side optical multiplexer-demultiplexer 62, the second asymmetric arm 63b, and the output-side optical multiplexer-demultiplexer 64.

The backward laser beam Lb from the semiconductor laser 5 received by the first optical coupler 61a and the backward laser beam Lb from the semiconductor laser 5 received by the second optical coupler 61b are demultiplexed and interfered by the input-side optical multiplexer-demultiplexer 62, and propagated from the second port of the input-side optical multiplexer-demultiplexer 62 to the first asymmetric arm 63a and from the fourth port of the input-side optical multiplexer-demultiplexer 62 to the second asymmetric arm 63b.

The laser beam propagated through the first asymmetric arm 63a and the laser beam propagated through the second asymmetric arm 63b are demultiplexed and interfered by the output-side optical multiplexer-demultiplexer 64, and propagated from the second port of the output-side optical multiplexer-demultiplexer 64 to the first optical receiver 65a and from the fourth port of the output-side optical multiplexer-demultiplexer 64 to the second optical receiver 65b.

The backward laser beam Lb from the semiconductor laser 5 received by the first optical coupler 61a is incident on both the first optical receiver 65a and the second optical receiver 65b although the ratio varies depending on the wavelength depending on the power branch ratio of each of the input-side optical multiplexer-demultiplexer 62 and the output-side optical multiplexer-demultiplexer 64.

Similarly, the backward laser beam Lb from the semiconductor laser 5 received by the second optical coupler 61b is incident on both the first optical receiver 65a and the second optical receiver 65b although the ratio varies depending on the wavelength depending on the power branch ratio of each of the input-side optical multiplexer-demultiplexer 62 and the output-side optical multiplexer-demultiplexer 64.

In short, the backward laser beam Lb from the semiconductor laser 5 received by the first optical coupler 61a and the backward laser beam Lb from the semiconductor laser 5 received by the second optical coupler 61b are demultiplexed and interfered by each of the input-side optical multiplexer-demultiplexer 62 and the output-side optical multiplexer-demultiplexer 64, and are propagated to the first optical receiver 65a and the second optical receiver 65b at a ratio determined by the input-side optical multiplexer-demultiplexer 62 and the output-side optical multiplexer-demultiplexer 64 depending on the wavelength.

Since the backward laser beam Lb from the semiconductor laser 5 received by the first optical coupler 61a and the backward laser beam Lb from the semiconductor laser 5 received by the second optical coupler 61b are each incident on the input-side optical multiplexer-demultiplexer 62 and the output-side optical multiplexer-demultiplexer 64 without being reflected, the total output of the input-side optical multiplexer-demultiplexer 62 and the output-side optical multiplexer-demultiplexer 64 can be regarded as power obtained by combining the backward laser beam Lb from the semiconductor laser 5 received by the first optical coupler 61a and the backward laser beam Lb from the semiconductor laser 5 received by the second optical coupler 61b.

The first optical receiver 65a receives the laser beam from the second port of the output-side optical multiplexer-demultiplexer 64, and outputs the photoelectrically converted photocurrent as a first monitor value.

The second optical receiver 65b receives the laser beam Lb from the second port of the output-side optical multiplexer-demultiplexer 64, and outputs the photoelectrically converted photocurrent as a second monitor value.

The photocurrent obtained from the first optical receiver 65a has wavelength dependence because the backward laser beam Lb from the semiconductor laser 5 received by the first optical coupler 61a and the backward laser beam from the semiconductor laser 5 received by the second optical coupler 61b are interfered by the input-side optical multiplexer-demultiplexer 62 and the output-side optical multiplexer-demultiplexer 64 constituting the interferometer.

Therefore, the first monitor value and the second monitor value also have wavelength dependence.

When the length (physical length) of the propagation path of light in the first asymmetric arm 63a is L₁ and the length (physical length) of the propagation path of light in the second asymmetric arm 63b is L₂, the relationship between L₁ and L₂ is expressed by the following Expression (1).

$${L}_{1} = {L}_{2} + Δ L \qquad ( 1 )$$

ΔL is a difference between the length of the optical waveguide in the first asymmetric arm 63a and the length of the optical waveguide in the second asymmetric arm 63b.

Note that a phase θ after the interference in the optical monitor 6, that is, a phase difference θ between the first monitor value and the second monitor value in the optical monitor 6 can be expressed by the following Expression (2).

$${n}_{0} \cdot {L}_{1} - {n}_{0} \cdot {L}_{2} = {n}_{0} Δ L = m \cdot λ = ( λ / 2 π ) \cdot θ \qquad ( 2 )$$

n₀ is a group refractive index of each of the first asymmetric arm 63a and the second asymmetric arm 63b, λ is a wavelength of the backward laser beam Lb, m is a coefficient connecting the wavelength λ and the optical path length nL, and is a variable proportional to the phase θ.

The phase difference θ changes depending on the temperature, and the group refractive index n₀, the length L₁ of the propagation path of light in the first asymmetric arm 63a, and the length L₂ of the propagation path of light in the second asymmetric arm 63b are determined in such a manner that the temperature derivative of the above Expression (2) is always 0, whereby the optical monitor 6 in which the first monitor value and the second monitor value do not have temperature dependence is obtained.

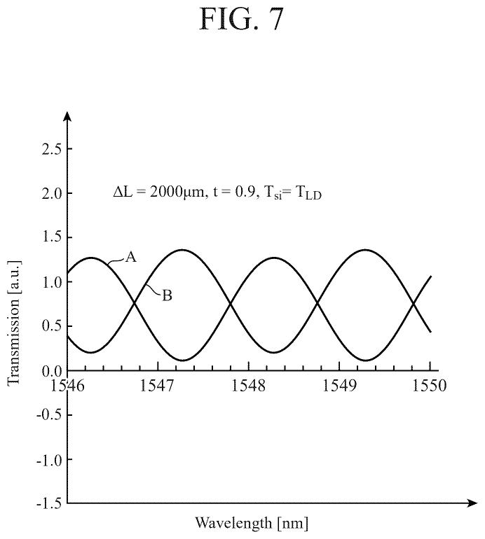

A waveform obtained by the first monitor value from the first optical receiver 65a is illustrated as a waveform A in FIG. 7 as an example, and a waveform obtained by the second monitor value from the second optical receiver 65b is illustrated as a waveform B in FIG. 7 as an example.

The waveforms illustrated in FIG. 7 are examples when ΔL is 2,000 μm, the electric field transmission coefficient t is 0.9, and Tₛᵢ=T_{LD}, and each indicate photocurrent values obtained by the first optical receiver 65a and the second optical receiver 65b.

In FIG. 7, the horizontal axis represents the wavelength of the backward laser beam Lb, and the vertical axis represents the intensity of the monitor value.

As understood from FIG. 7, the waveform A obtained by the first monitor value and the waveform B obtained by the second monitor value have a reverse phase relationship, that is, an inverted waveform, and have phases shifted by 180 degrees.

Therefore, in the control unit 9, if the sum is simply obtained on the basis of the first monitor value based on the photocurrent from the first optical receiver 65a and the second monitor value by the photocurrent from the second optical receiver 65b, the optical power monitor value Ip, which is the total value of the first monitor value and the second monitor value, can be calculated.

That is, since the total value of the photocurrent from the first optical receiver 65a, which is the first monitor value from the first optical receiver 65a, and the photocurrent from the second optical receiver 65b, which is the second monitor value from the second optical receiver 65b, is proportional to the total power of the backward laser beam Lb from the semiconductor laser 5 received by the first optical coupler 61a and the backward laser beam Lb from the semiconductor laser 5 received by the second optical coupler 61b, the total value of the first monitor value and the second monitor value can be used as the optical power monitor value Ip.

The obtained optical power monitor value Ip is twice as large as that using one optical coupler and one optical receiver.

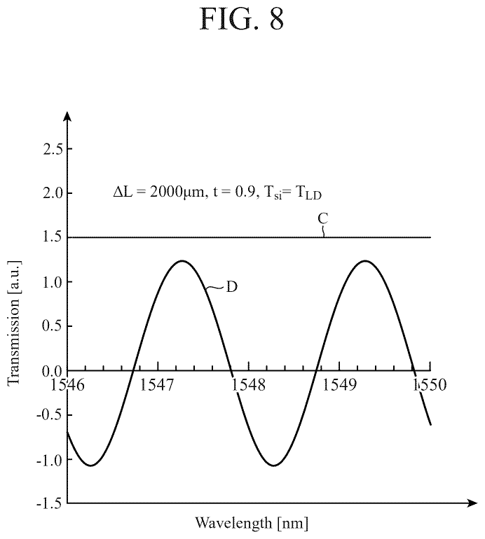

FIG. 8 illustrates, as an example, a waveform C obtained by the sum of the first monitor value and the second monitor value.

The waveform C illustrated in FIG. 8 is an example when ΔL is 2,000 μm, the electric field transmission coefficient t is 0.9, and Tₛᵢ=T_{LD}, and is a value obtained by simply adding the photocurrent value obtained by first optical receiver 65a and the photocurrent value obtained by the second optical receiver 65b.

In FIG. 8, the horizontal axis represents the wavelength of the backward laser beam Lb, and the vertical axis represents the intensity.

In addition, since the photocurrent from the first optical receiver 65a and the photocurrent from the second optical receiver 65b have wavelength dependence, a difference value between the first monitor value and the second monitor value can be used as the wavelength monitor value Iλ.

FIG. 8 illustrates, as an example, a waveform D obtained by a difference value between the first monitor value and the second monitor value.

The waveform D illustrated in FIG. 8 is an example when ΔL is 2,000 μm, the electric field transmission coefficient t is 0.9, and Tₛᵢ=T_{LD}, and is a value obtained by simply subtracting the photocurrent value obtained by first optical receiver 65a from the photocurrent value obtained by the second optical receiver 65b.

By taking the difference between the first monitor value and the second monitor value, it is possible to obtain a gradient of the intensity of the photocurrent that is twice the gradient of the intensity of the photocurrent flowing through the optical receiver of that using one optical coupler and one optical receiver.

The wavelength monitor value Iλ changes not only in the wavelength of the backward laser beam Lb of the semiconductor laser 5 but also in the light intensity of the backward laser beam Lb.

Therefore, by dividing the wavelength monitor value Iλ by the optical power monitor value Ip, the wavelength monitor value Iλ/Ip based only on the wavelength of the backward laser beam Lb is obtained.

The first optical receiver 65a and the second optical receiver 65b change in sensitivity due to a temperature change, but a wavelength monitor value with high accuracy can be obtained by dividing the wavelength monitor value Iλ by the optical power monitor value Ip and normalizing the wavelength monitor value with the optical power monitor value Ip.

In the optical module according to the first embodiment, the optical monitor 6 includes the first optical coupler 61a and the second optical coupler 61b, and constitutes an optical interferometer in which the first path from the first optical coupler 61a to the first optical receiver 65a and the second path from the second optical coupler 61b to the second optical receiver 65b are asymmetric, the first monitor value is obtained from the first optical receiver 65a, the second monitor value is obtained from the second optical receiver 65b, and the optical power monitor value Ip and the wavelength monitor value Iλ/Ip are obtained.

Therefore, in the optical module according to the first embodiment, the light receiving area of the backward laser beam Lb is doubled by the first optical coupler 61a and the second optical coupler 61b with respect to one optical coupler, as compared with a case where one optical coupler receives the backward laser beam Lb from the semiconductor laser 5, and the backward laser beam Lb received by the optical coupler is branched into two halves to obtain the optical power monitor value Ip and the wavelength monitor value Iλ/Ip by each.

Furthermore, since the wavelength monitor value Iλ is obtained by the difference value between the first monitor value and the second monitor value, the wavelength monitor value Iλ can be obtained by the gradient of the intensity of the photocurrent twice the gradient of the intensity of the photocurrent flowing through the optical receiver of that using one optical coupler and one optical receiver.

Therefore, it is possible to use the backward laser beam Lb from the semiconductor laser 5 four times as large as that using one assumed optical coupler to obtain the optical power monitor value Ip and the wavelength monitor value Iλ/Ip.

As a result, the optical monitor 6 having four times the sensitivity to the backward laser beam Lb from the semiconductor laser 5 can be obtained, and the optical power monitor value Ip and the wavelength monitor value Iλ/Ip with high accuracy can be obtained.

The wavelength of the forward laser beam Lf of the semiconductor laser 5 can be adjusted by adjusting the temperature of the semiconductor laser 5.

Temperatures of the semiconductor laser 5 and the optical monitor 6 are regulated by heat on the mounting surface 2b of the temperature adjuster 2 via the base 3, a temperature rise in the semiconductor laser 5 and a temperature rise in the optical monitor 6 are the same.

The wavelength monitor value Iλ/Ip has a downward gradient with respect to the temperature rise in the optical monitor 6.

It is possible to know a wavelength shift in the laser beam of the semiconductor laser 5 by knowing the wavelength monitor value Iλ/Ip.

When the forward laser beam Lf from the semiconductor laser 5 deviates from the target wavelength (hereinafter, referred to as a target value λ_target) of the forward laser beam Lf from the semiconductor laser 5, the wavelength monitor value Iλ/Ip also deviates.

Therefore, the temperature in the semiconductor laser 5 and the temperature in the optical monitor 6 are adjusted by controlling the value of the photocurrent supplied to the temperature adjuster 2 in such a manner that the wavelength monitor value Iλ/Ip does not deviate from the wavelength set value (±10% of the target value Iλ_target).

As a result, precise control can be performed on the single wavelength of the laser beam of the semiconductor laser 5.

In this example, the optical monitor 6 further includes the phase adjuster 66 disposed on the second asymmetric arm 63b.

The phase adjuster 66 sets the phase state of the photocurrent output from the optical monitor 6 to a position where the wavelength dependence of the photocurrent output from the optical monitor 6 at the target wavelength (hereinafter, referred to as the target value λ_target) of the forward laser beam Lf from the semiconductor laser 5 is the largest.

The phase adjuster 66 is, for example, a heater.

By causing a photocurrent to flow through the heater serving as the phase adjuster 66 in such a manner that the target value Iλ_target becomes a value of the wavelength monitor value Iλ/Ip suitable for control, the second path of the optical monitor 6, in this example, the second asymmetric arm 63b is heated to adjust the temperature in the second asymmetric arm 63b.

The target value Iλ_target is determined by adjusting the temperature in the second path of the optical monitor 6 by the phase adjuster 66 so as to be the wavelength monitor value Iλ/Ip near the median value in a region where the gradient of the wavelength dependence is large with respect to a change in the temperature of the optical monitor 6.

Note that the temperature in the first path of the optical monitor 6, for example, the first asymmetric arm 63a may be adjusted by the phase adjuster 66.

The phase adjuster 66 is not limited to the heater as long as it can change the phase state of the photocurrent output from the optical monitor 6, and may be a phase changer by photocurrent injection or photocurrent extraction by a pn junction, or a quantum confinement Stark effect or a Pockels effect by voltage application, such as a pin-type photocurrent injection refractive index adjuster or a photocurrent extraction refractive index adjuster.

Note that the optical monitor 6 may be a planar waveguide optical monitor in which the first optical coupler 61a, the second optical coupler 61b, the input-side optical multiplexer-demultiplexer 62, the first asymmetric arm 63a, the second asymmetric arm 63b, the output-side optical multiplexer-demultiplexer 64, the first optical receiver 65a, and the second optical receiver 65b are integrated on an inner plane of an indium phosphide (InP) substrate 6A which is a compound semiconductor.

The optical monitor 6 may be a planar waveguide optical monitor in which the first optical coupler 61a, the second optical coupler 61b, the input-side optical multiplexer-demultiplexer 62, the first asymmetric arm 63a, the second asymmetric arm 63b, the output-side optical multiplexer-demultiplexer 64, the first optical receiver 65a, and the second optical receiver 65b are integrated on a flat surface of the glass substrate 6A.

Note that the first optical coupler 61a, the second optical coupler 61b, the input-side optical multiplexer-demultiplexer 62, the first asymmetric arm 63a, the second asymmetric arm 63b, the output-side optical multiplexer-demultiplexer 64, the first optical receiver 65a, and the second optical receiver 65b are not necessarily integrated, and individual components may be modularized.

Each of the first optical receiver 65a and the second optical receiver 65b may be an InP-based optical receiver or a GaAs-based optical receiver.

As illustrated in FIG. 6, the temperature adjuster 2, the semiconductor laser 5, and the optical monitor 6 are controlled by the control unit 9.

The control unit 9 exchanges signals with the semiconductor laser 5, the optical monitor 6, and the temperature adjuster 2, and controls the photocurrent and voltage to each of the semiconductor laser 5, the optical monitor 6, and the temperature adjuster 2 to control the light intensity of the laser beam from the semiconductor laser 5 and the wavelength of the laser beam.

The control unit 9 receives the first monitor value that is the photocurrent from the first optical receiver 65a and the second monitor value that is the photocurrent from the second optical receiver 65b, and calculates the optical power monitor value Ip that is the total value of the first monitor value and the second monitor value, the wavelength monitor value Iλ that is the difference value between the first monitor value and the second monitor value, and the wavelength monitor value Iλ/Ip that is the ratio between the optical power monitor value Ip and the wavelength monitor value Iλ.

In this example, the optical power monitor value Ip is a value obtained by adding the first monitor value obtained from the first optical receiver 65a and the second monitor value obtained from the second optical receiver 65b (see the straight line C in FIG. 4).

In this example, the wavelength monitor value Iλ is a value obtained by subtracting the first monitor value obtained from the first optical receiver 65a from the second monitor value obtained from the second optical receiver 65b (see the waveform curve D in FIG. 4).

The control unit 9 controls the driving photocurrent supplied to the semiconductor laser 5 in such a manner that the calculated optical power monitor value Ip falls within a range of ±10% of the target value Ip_target of the optical power monitor value that is a photocurrent set value with respect to the semiconductor laser 5.

The control unit 9 controls the photocurrent supplied to the temperature adjuster 2 in such a manner that the calculated optical power monitor value Ip falls within a range of the photocurrent set value of ±10% of the target value Ip_target of the optical power monitor value with respect to the temperature adjuster 2.

The control unit 9 supplies a photocurrent for heating the mounting surface 2b of the temperature adjuster 2 to the temperature adjuster 2 when the optical power monitor value Ip is larger than the photocurrent set value, and supplies a photocurrent for cooling the mounting surface 2b of the temperature adjuster 2 to the temperature adjuster 2 when the optical power monitor value Ip is smaller than the photocurrent set value.

As a result, the temperature adjuster 2 performs control to increase the temperature to be given to the semiconductor laser 5 and the optical monitor 6 when the optical power monitor value Ip is larger than a photocurrent set value, and to decrease the temperature to be given to the semiconductor laser 5 and the optical monitor 6 when the optical power monitor value Ip is smaller than the photocurrent set value.

Note that the control unit 9 controls the photocurrent supplied to the temperature adjuster 2 in such a manner that the calculated wavelength monitor value Iλ/Ip falls within a range of a wavelength set value of ±10% of the target value Iλ_target of the wavelength monitor value Iλ/Ip when the wavelength λLD of the laser beam of the semiconductor laser 5 is set to the target value λ_target.

When the wavelength monitor value Iλ/Ip deviates from the wavelength set value, the control unit 9 supplies a photocurrent for changing the temperature of the mounting surface 2b to the temperature adjuster 2.

In the present example, when the wavelength monitor value Iλ/Ip is larger than the wavelength set value, the control unit 9 supplies a photocurrent for heating the mounting surface 2b of the temperature adjuster 2 to the temperature adjuster 2, and when the wavelength monitor value Iλ/Ip is smaller than the wavelength set value, the control unit 9 supplies a photocurrent for cooling the mounting surface 2b of the temperature adjuster 2 to the temperature adjuster 2.

As a result, the temperature adjuster 2 performs control to increase the temperature to be given to the semiconductor laser 5 and the optical monitor 6 when the wavelength monitor value Iλ/Ip is larger than the wavelength set value, and to decrease the temperature to be given to the semiconductor laser 5 and the optical monitor 6 when the wavelength monitor value Iλ/Ip is smaller than the wavelength set value.

Further, the temperature adjuster 2 performs control to increase the driving photocurrent to be supplied to the semiconductor laser 5 when the optical power monitor value Ip becomes smaller than the photocurrent set value by increasing the temperature to be given to the semiconductor laser 5 and the optical monitor 6 when the wavelength monitor value Iλ/Ip is larger than the wavelength set value, and decrease the driving photocurrent to be supplied to the semiconductor laser 5 when the optical power monitor value Ip becomes larger than the photocurrent set value by decreasing the temperature to be given to the semiconductor laser 5 and the optical monitor 6 when the wavelength monitor value Iλ/Ip is smaller than the wavelength set value.

The control unit 9 supplies, to the phase adjuster 66, a photocurrent of a target value Ih_target at the time of obtaining the optical output of the laser beam in which the light intensity of the laser beam of the semiconductor laser 5 becomes the target value and the wavelength λLD of the laser beam of the semiconductor laser 5 becomes the target value λ_target.

As a result, the heater as the phase adjuster 66 heats the optical monitor 6, specifically, adjusts the temperature in the second path of the optical monitor 6, in this example, the second asymmetric arm 63b, under the control of the control unit 9.

The control unit 9 and the optical monitor 6 constitute a wavelength locker for wavelength control of the laser beam from the semiconductor laser 5.

The optical module and the control unit 9 constitute an optical module device.

The semiconductor laser 5, the optical monitor 6, and the temperature adjuster 2 are electrically connected to the lead pins P1 to P6 by wires (not illustrated) such as gold wires by wire bonding in order to exchange signals with the control unit 9.

Each of the lead pins P1 to P6 penetrates each of the through holes of the stem 1, and is fixed to the stem 1 by sealing glass filled and solidified between the lead pins P1 to P6 and the through holes. The sealing glass electrically insulates each of the lead pins P1 to P6 from the stem 1 and maintains airtightness.

Connection of inner lead portions of the lead pins P1 to P6 exposed from the inner flat surface of the stem 1 is, for example, as follows. However, the relationship between the lead pins P1 to P6 and each component is an example, and the present invention is not limited thereto.

The lead pin P1 is connected to one electrode of the semiconductor laser 5, and transmits the driving photocurrent from the control unit 9 to the semiconductor laser 5. The lead pin P1 is a main signal lead pin for the semiconductor laser 5.

The lead pin P2 is connected to the first optical receiver 65a of the optical monitor 6, and transmits a photocurrent indicating the first monitor value from the first optical receiver 65a to the control unit 9. The lead pin P2 is a first monitor lead pin for the optical monitor 6.

The lead pin P3 is connected to the second optical receiver 65b of the optical monitor 6, and transmits a photocurrent indicating the second monitor value from the second optical receiver 65b to the control unit 9. The lead pin P3 is a second monitor lead pin for the optical monitor 6.

The lead pin P4 and the lead pin P5 are connected to a pair of electrodes in the temperature adjuster 2, and transmit a photocurrent supplied from the control unit 9 to the temperature adjuster 2. The lead pins P4 and P5 are a pair of temperature control lead pins for the temperature adjuster 2.

The lead pin P6 is connected to the phase adjuster 66 and transmits the photocurrent supplied from the control unit 9 to the phase adjuster 66. The lead pin P6 is a phase adjustment lead pin for the phase adjuster 66.

One end face of the grounding lead pin P7 is in contact with the outer flat surface 1b of the stem 1 and joined by electric welding or brazing, and the grounding lead pin P7 is fixed to the stem 1.

The grounding lead pin P7 is electrically grounded, and the stem 1 is set to the ground potential by the grounding lead pin P7. That is, the stem 1 also serves as a ground node.

The optical module according to the first embodiment only needs to include a total of seven lead pins including six signal lead pins P1 to P6 for respective components and one grounding lead pin P7, and the optical module can be constituted by a small number of lead pins.

As a result, a standard CAN package having a diameter of 5.6 mm, in which the number of lead pins is limited to 7, can be used, and downsizing can be achieved.

Next, an operation of the optical module according to the first embodiment will be described.

The optical module is a module on which the semiconductor laser 5, which is a laser chip that has been confirmed to obtain an optical output equal to or higher than a target within an operating temperature range and to obtain a target oscillation wavelength within a controllable temperature range, is mounted.

First, as a preliminary preparation for operating the optical module, the following is performed.

There are acquired a target value ILD_target of the driving photocurrent to be supplied to the semiconductor laser 5, a target value ITEC_target of the photocurrent to be supplied to the temperature adjuster 2, and the target value Ih_target of the photocurrent to be supplied to the phase adjuster 66 when the optical output in which the wavelength λLD becomes the target value λ_target and the light intensity becomes the target value Ip_target of the optical power monitor value Ip is obtained from the semiconductor laser 5.

These target values are acquired using a generally known light intensity measuring device and light wavelength measuring device.

Further, at the same timing, when the target value Ip_target of the optical power monitor value Ip at which the light intensity becomes the target value and the optical output in which the wavelength λLD becomes the target value λ_target are obtained from the semiconductor laser 5, there is acquired the wavelength dependence of the target value Ip_target of the optical power monitor value Ip and the target value Iλ_target of the wavelength monitor value Iλ/Ip when the wavelength λLD becomes the target value λ_target and the wavelength monitor value Iλ/Ip around the target value Iλ_target.

In the semiconductor laser 5, the photocurrent value ILD of the driving photocurrent and the optical power monitor value Ip are in a proportional relationship, and as the temperature of the semiconductor laser 5 is lower, the optical output increases, that is, the optical power monitor value Ip increases.

In the present example, the driving photocurrent of the target value ILD_target is supplied to the semiconductor laser 5, and the temperature of the semiconductor laser 5 at which the optical output at which the target value Ip_target of the optical power monitor value Ip and the wavelength λLD become the target value λ_target is obtained is 55° C.

Further, the target value Iλ_target of the wavelength monitor value Iλ/Ip is set to a region near the median value of the wavelength monitor value Iλ/Ip when the temperature of the semiconductor laser 5 and the temperature of the optical monitor 6 are changed and where the gradient of the wavelength dependence is large.

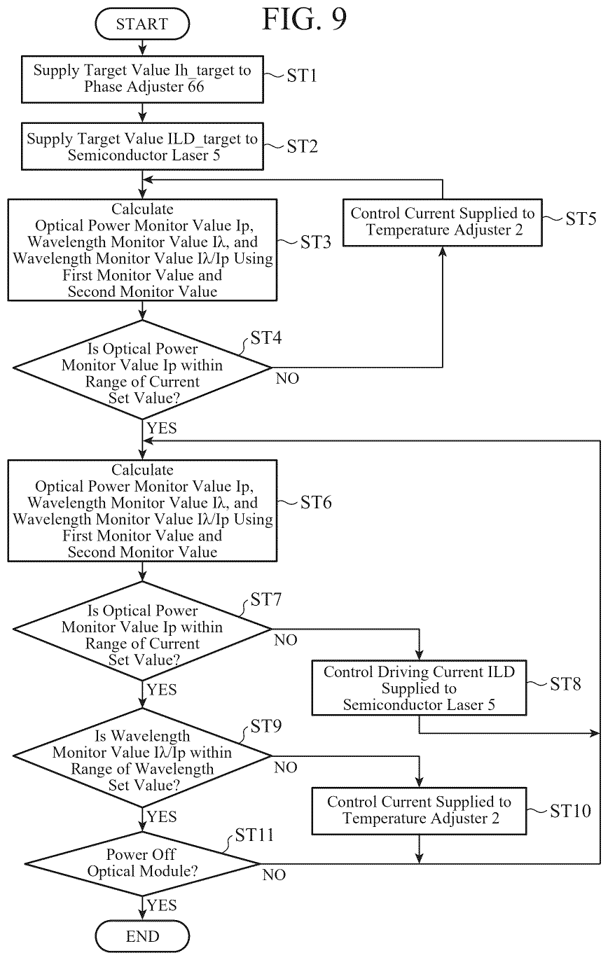

Next, the operation of the optical module will be described mainly with reference to FIG. 9.

When the optical module is activated, the control unit 9 supplies the photocurrent of the target value Ih_target to the phase adjuster 66 (step ST1).

Subsequently, the control unit 9 supplies the driving photocurrent of the target value ILD_target to the semiconductor laser 5 (step ST2).

When the driving photocurrent of the target value ILD_target is supplied, the semiconductor laser 5 emits the forward laser beam Lf to the outside of the cap 7 through the window 8, and emits the backward laser beam Lb to the first optical coupler 61a and the second optical coupler 61b in the optical monitor 6.

The optical monitor 6 on which the backward laser beam Lb is incident monitors the light intensity of the laser beam from the semiconductor laser 5 in a mutually inverted relationship in which phases are shifted from each other. That is, the optical monitor 6 acquires the first monitor value and the second monitor value in an asymmetric relationship.

That is, the laser beam from the first optical coupler 61a that has received the backward laser beam Lb of the semiconductor laser 5 enters the first optical waveguide 62a constituting the input-side optical multiplexer-demultiplexer 62 from the first port of the input-side optical multiplexer-demultiplexer 62.

On the other hand, the laser beam from the second optical coupler 61b that has received the backward laser beam Lb of the semiconductor laser 5 enters the second optical waveguide 62b constituting the input-side optical multiplexer-demultiplexer 62 from the third port of the input-side optical multiplexer-demultiplexer 62.

The laser beam from the first optical coupler 61a and the laser beam from the second optical coupler 61b incident on the input-side optical multiplexer-demultiplexer 62 are demultiplexed and interfered by the input-side optical multiplexer-demultiplexer 62, and propagated from the second port of the input-side optical multiplexer-demultiplexer 62 to the first asymmetric arm 63a and from the fourth port of the input-side optical multiplexer-demultiplexer 62 to the second asymmetric arm 63b.

The laser beam propagated through the first asymmetric arm 63a is propagated from the first port of the output-side optical multiplexer-demultiplexer 64 to the third optical waveguide 64a constituting the output-side optical multiplexer-demultiplexer 64.

The laser beam propagated through the second asymmetric arm 63b is propagated from the third port of the output-side optical multiplexer-demultiplexer 64 to the fourth optical waveguide 64b constituting the output-side optical multiplexer-demultiplexer 64.

Each of the laser beam propagated through the first asymmetric arm 63a and the laser beam propagated through the second asymmetric arm 63b and propagated to the output-side optical multiplexer-demultiplexer 64 is demultiplexed and interfered by the output-side optical multiplexer-demultiplexer 64, is incident on the first optical receiver 65a from the second port of the output-side optical multiplexer-demultiplexer 64, and is incident on the second optical receiver 65b from the fourth port of the output-side optical multiplexer-demultiplexer 64.

The laser beam incident on the first optical receiver 65a is photoelectrically converted by the first optical receiver 65a, and a photocurrent indicating the first monitor value is output to the control unit 9.

The laser beam incident on the second optical receiver 65b is photoelectrically converted by the second optical receiver 65b, and a photocurrent indicating the second monitor value is output to the control unit 9.

The relationship between the first monitor value and the second monitor value is the relationship between the waveform curve A and the waveform curve B illustrated in FIG. 7.

The control unit 9 converts the first monitor value based on the photocurrent into a voltage, and further converts analog to digital to obtain the first monitor value as digital information.

The control unit 9 converts the second monitor value based on the photocurrent into a voltage, and further converts analog to digital to obtain the second monitor value as digital information.

Note that the conversion from the photocurrent to the voltage in the control unit 9 may be performed by the optical monitor 6.

In short, the control unit 9 only needs to obtain the first monitor value based on the digital information by the output from the first optical receiver 65a and obtain the second monitor value based on the digital information by the output from the second optical receiver 65b.

The control unit 9 that has obtained the first monitor value and the second monitor value calculates the optical power monitor value Ip that is the total value of the first monitor value and the second monitor value, wavelength monitor value Iλ that is the difference value between the first monitor value and the second monitor value, and the wavelength monitor value Iλ/Ip that is the ratio between the optical power monitor value Ip and the wavelength monitor value Iλ (step ST3).

The control unit 9 determines whether or not the optical power monitor value Ip is within the range of the photocurrent set value (step ST4).

The control unit 9 proceeds to step ST5 when the optical power monitor value Ip is out of the range of the photocurrent set value, and proceeds to step ST6 when the optical power monitor value Ip is within the range of the photocurrent set value.

The photocurrent set value is set to, for example, ±10% of the target value Ip_target of the optical power monitor value Ip.

Step ST5 is a temperature adjusting step of a preceding stage of controlling the photocurrent supplied to the temperature adjuster 2.

Step ST5 includes a pre-stage temperature increasing step of increasing the temperature to be given to the semiconductor laser 5 and the optical monitor 6 by the temperature adjuster 2 when the optical power monitor value Ip calculated by the control unit 9 in step ST3 is larger than the photocurrent set value, and a pre-stage temperature decreasing step of decreasing the temperature to be given to the semiconductor laser 5 and the optical monitor 6 by the temperature adjuster 2 when the optical power monitor value Ip is smaller than the photocurrent set value.

When the driving photocurrent of the target value ILD_target is supplied to the semiconductor laser 5, for example, when the optical power monitor value Ip calculated by the control unit 9 is larger than the photocurrent set value, the temperature of the semiconductor laser is lower than 55° C.

Therefore, the control unit 9 controls the photocurrent supplied to the temperature adjuster 2 so as to heat the mounting surface 2b of the temperature adjuster 2 with respect to the temperature adjuster 2, and returns to step ST3.

As a result, the semiconductor laser 5 and the optical monitor 6 are heated through the base 3, and the temperature of the semiconductor laser 5 and the temperature of the optical monitor 6 rise to 55° C.

On the other hand, when the driving photocurrent of the target value

ILD_target is supplied to the semiconductor laser 5, for example, when the optical power monitor value Ip calculated by the control unit 9 in step ST3 is smaller than the photocurrent set value, the temperature of the semiconductor laser is higher than 55° C.

Therefore, the control unit 9 controls the photocurrent supplied to the temperature adjuster 2 so as to cool the mounting surface 2b of the temperature adjuster 2 with respect to the temperature adjuster 2, and returns to step ST3.

As a result, the semiconductor laser 5 and the optical monitor 6 are cooled via the base 3, and the temperature of the semiconductor laser 5 and the temperature of the optical monitor 6 decrease to 55° C.

By repeating step ST5, when the temperature of the semiconductor laser 5 and the temperature of the optical monitor 6 are adjusted by the temperature adjuster 2 and the optical power monitor value Ip calculated by the control unit 9 falls within the range of the photocurrent set value, the control unit 9 ends the temperature adjusting step of the preceding stage, and proceeds to step ST6.

The process proceeds to a wavelength locker step after step ST6.

Similarly to step ST3, step ST6 is a step of calculating the optical power monitor value Ip, the wavelength monitor value Iλ, and the wavelength monitor value Iλ/Ip.

Step ST7 is a step in which the control unit 9 determines whether or not the optical power monitor value Ip is within the range of the photocurrent set value.

The control unit 9 proceeds to step ST8 when the optical power monitor value Ip is out of the range of the photocurrent set value, and proceeds to step ST9 when the optical power monitor value Ip is within the range of the photocurrent set value.

Immediately after proceeding from step ST5 to step ST7, the optical power monitor value Ip is within the range of the photocurrent set value, and thus the process proceeds to step ST9.

Step ST9 is a step in which the control unit 9 determines whether or not the wavelength monitor value Iλ/Ip is within the range of the wavelength set value.

The control unit 9 proceeds to step ST10 when the wavelength monitor value Iλ/Ip is out of the range of the wavelength set value, and proceeds to step ST11 when the wavelength monitor value Iλ/Ip is within the range of the wavelength set value.

The wavelength set value is set to, for example, ±10% of the target value Iλ_target of the wavelength monitor value Iλ/Ip.

Step ST10 is a temperature adjusting step of controlling the photocurrent supplied to the temperature adjuster 2.

The temperature adjusting step is a step of adjusting the temperature to be given to the semiconductor laser 5 and the optical monitor 6 by the temperature adjuster 2 when the wavelength monitor value Iλ/Ip deviates from the wavelength set value, and in this example, includes the following temperature increasing step and temperature decreasing step.

That is, step ST10 includes a temperature increasing step of causing, by the control unit 9, the temperature adjuster 2 to increase the temperature to be given to the semiconductor laser 5 and the optical monitor 6 when the wavelength monitor value Iλ/Ip calculated by the control unit 9 in step ST6 is larger than the wavelength set value, and a temperature decreasing step of causing the temperature adjuster 2 to decrease the temperature to be given to the semiconductor laser 5 and the optical monitor 6 when the wavelength monitor value Iλ/Ip is smaller than the wavelength set value.

In the temperature increasing step, the control unit 9 controls the photocurrent supplied to the temperature adjuster 2 so as to heat the mounting surface 2b of the temperature adjuster 2 with respect to the temperature adjuster 2, increases the temperature of the semiconductor laser 5 and the temperature of the optical monitor 6, increases the wavelength λLD of the laser beam from the semiconductor laser 5, reduces the wavelength monitor value Iλ/Ip, and returns to step ST7 after being through step ST6.

On the other hand, in the temperature decreasing step, the control unit 9 controls the photocurrent supplied to the temperature adjuster 2 in such a manner as to cool the mounting surface 2b of the temperature adjuster 2 with respect to the temperature adjuster 2, decreases the temperature of the semiconductor laser 5 and the temperature of the optical monitor 6, reduces the wavelength λLD of the laser beam from the semiconductor laser 5, increases the wavelength monitor value Iλ/Ip, and returns to step ST7 after being through step ST6.

In the temperature increasing step in step ST10, the temperature of the semiconductor laser 5 is also increased, and as a result, the light intensity of the laser beam from the semiconductor laser 5 is reduced, and the optical power monitor value Ip is reduced.

On the other hand, in the temperature decreasing step in step ST10, the temperature of the semiconductor laser 5 is also decreased, and as a result, the light intensity of the laser beam from the semiconductor laser 5 is increased and the optical power monitor value Ip is increased.

Therefore, when the temperature by the temperature adjuster 2 is adjusted in order to adjust the wavelength λLD of the laser beam from the semiconductor laser 5 in step ST10, the optical power monitor value Ip also changes, and thus, in step ST7, the control unit 9 determines whether or not the optical power monitor value Ip is within the range of the photocurrent set value.

In step ST7, when the optical power monitor value Ip calculated by the control unit 9 in step ST6 is within the range of the photocurrent set value, the process proceeds to step ST9, and the processing is repeated from step ST10 to step ST7.

On the other hand, in step ST7, when the optical power monitor value Ip calculated by the control unit 9 in step ST6 is out of the range of the photocurrent set value, the process proceeds to step ST8.

Step ST8 is a driving photocurrent control step of controlling the driving photocurrent to be supplied to the semiconductor laser 5.

Step ST8 includes a driving photocurrent increasing step of increasing the driving photocurrent supplied to the semiconductor laser 5 when the temperature to be given to the semiconductor laser 5 and the optical monitor 6 by the temperature adjuster 2 increases by the temperature increasing step in step ST10 and the optical power monitor value Ip calculated by the control unit 9 becomes smaller than the photocurrent set value in step ST6, and a driving photocurrent decreasing step of decreasing the driving photocurrent supplied to the semiconductor laser 5 when the temperature to be given to the semiconductor laser 5 and the optical monitor 6 by the temperature adjuster 2 decreases by the temperature decreasing step in step ST10 and the optical power monitor value Ip calculated by the control unit 9 becomes larger than the photocurrent set value.

Therefore, the control unit 9 repeats step ST8 until the optical power monitor value Ip falls within the range of the photocurrent set value, and when the optical power monitor value Ip falls within the range of the photocurrent set value, the control unit 9 proceeds to step ST9, and the temperature adjusting step of controlling the photocurrent to be supplied to the temperature adjuster 2 in step ST10 is repeated.

That is, the repetition of the loop of the temperature adjusting step of step ST7-step ST9-step ST10-step ST6-step ST7-step ST9 and the repetition of the loop of the driving photocurrent control step of step ST7-step ST8-step ST6-step ST7 are wavelength locker steps.

By this wavelength locker step, the optical power monitor value Ip falls within the range of the photocurrent set value, and the wavelength monitor value Iλ/Ip falls within the range of the wavelength set value.

As a result, the semiconductor laser 5 enters a stable operation satisfying both of the condition that the light intensity of the laser beam from the semiconductor laser 5 is based on the target value Ip_target and the condition that the wavelength of the laser beam from the semiconductor laser 5 is based on the target value Iλ_target of the wavelength monitor value Iλ/Ip, in other words, the target value λ_target.

When the semiconductor laser 5 enters stable operation, the process proceeds to step ST11.

In step ST11, until the optical module is powered off, the control unit 9 continues monitoring the first monitor value by the first optical receiver 65a and the second monitor value by the second optical receiver 65b to continue monitoring the optical power monitor value Ip and the wavelength monitor value Iλ/Ip, continues the wavelength locker step until the optical module is powered off, and ends the wavelength locker step when the optical module is powered off.

After the semiconductor laser 5 enters stable operation, until the optical power monitor value Ip falls outside the range of the photocurrent set value or the wavelength monitor value Iλ/Ip falls outside the range of the wavelength set value, the semiconductor laser 5 operates with the driving photocurrent set by the wavelength locker step, the temperature adjuster 2 operates with the supplied photocurrent set by the wavelength locker step, and the semiconductor laser 5 continues the stable operation.

When the optical power monitor value Ip falls outside the range of the photocurrent set value or the wavelength monitor value Iλ/Ip falls outside the range of the wavelength set value, a wavelength lock function by the wavelength locker step works, and the control unit 9 repeats the loop of the temperature adjusting step of step ST7-step ST9-step ST10-step ST6-step ST7-step ST9 and repeats the loop of the driving photocurrent control step of step ST7-step ST8-step ST6-step ST7.

As a result, the semiconductor laser 5 again enters stable operation satisfying both of the condition that the light intensity of the laser beam from the semiconductor laser 5 is based on the target value Ip_target and the condition that the wavelength of the laser beam from the semiconductor laser 5 is based on the target value Iλ_target of the wavelength monitor value Iλ/Ip.

Next, a result of verification of a relationship between the backward laser beam Lb of the semiconductor laser 5 and the first optical coupler 61a and the second optical coupler 61b in a case where a mounting deviation occurs between the semiconductor laser 5 and the optical monitor 6 will be described.

When there is a deviation in the relationship between the backward laser beam Lb of the semiconductor laser 5 and the first optical coupler 61a and the second optical coupler 61b, a phase difference and an optical power difference are generated between the coupling light beam of the backward laser beam Lb of the semiconductor laser 5 and the first optical coupler 61a and the coupling light beam of the backward the second optical coupler 61b.

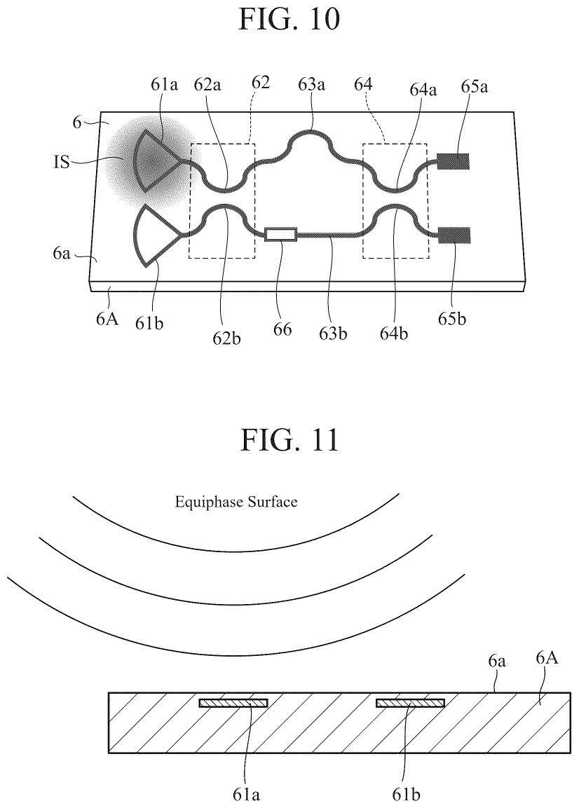

That is, as illustrated in FIG. 10, when the first optical coupler 61a is shifted to the center axis of the backward laser beam Lb of the semiconductor laser 5, an equiphase surface of the backward laser beam Lb of the semiconductor laser 5 with respect to the first optical coupler 61a and the second optical coupler 61b is as illustrated in FIG. 11.

As a result, a phase difference and an optical power difference due to mounting deviation are generated between the coupling light beam of the backward laser beam Lb of the semiconductor laser 5 and the first optical coupler 61a and the coupling light beam of the backward laser beam Lb of the semiconductor laser 5 and the second optical coupler 61b.

In FIG. 10, IS indicates a schematic light distribution of the backward laser beam Lb of the semiconductor laser 5 with respect to the first optical coupler 61a and the second optical coupler 61b.

The verification was performed assuming that the wavelength of the laser beam of the semiconductor laser 5 is 1.55 μm, the first optical coupler 61a and the second optical coupler 61b are grating couplers, and the distance between the emission surface of the laser beam of the semiconductor laser and the grating couplers is 0.3 mm.

Within the range of this assumed mounting deviation, it has been confirmed that a change from 1:1 to 2:1 occurs as a power branch ratio in the coupling light beam of the laser beam of the semiconductor laser and the first optical coupler 61a and the second optical coupler 61b, and a change from 0 degrees to 150 degrees occurs as a phase difference between the coupling light beam of the both.

Within the range of this assumed mounting deviation, in each of the electric field transmission coefficients t of the input-side optical multiplexer-demultiplexer 62 and the output-side optical multiplexer-demultiplexer 64 of 0.3, 0.5, 0.7, and 0.9, the gradient of the photocurrent by the first optical receiver 65a and the second optical receiver 65b with respect to the power branch ratio in the coupling light beam of the first optical coupler 61a and the second optical coupler 61b, that is, the gradient of the output of the so-called optical monitor was estimated.

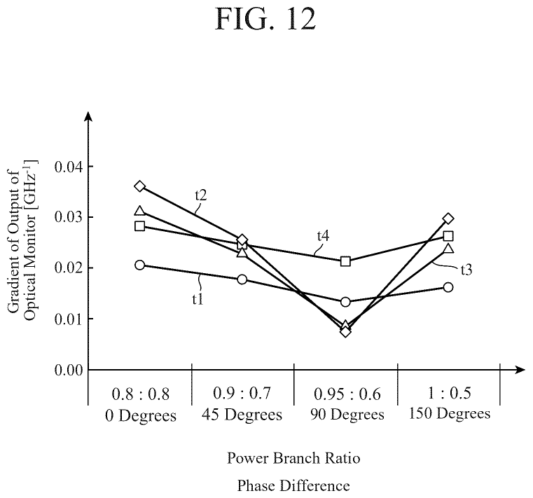

The result of trial calculation is illustrated in FIG. 12.

In FIG. 12, the horizontal axis indicates the power branch ratio in the coupling light beam of the first optical coupler 61a and the second optical coupler 61b in the upper part, the phase difference in the lower part, and the vertical axis indicates the gradient of the output of the optical monitor.

A line t1 to a line t4 indicate the electric field transmission coefficients t set for each of the input-side optical multiplexer-demultiplexer 62 and the output-side optical multiplexer-demultiplexer 64.

The line t1 has an electric field transmission coefficient t of 0.3, the line t2 has an electric field transmission coefficient t of 0.5, the line t3 has an electric field transmission coefficient t of 0.7, and the line t4 has an electric field transmission coefficient t of 0.9.

For each of the electric field transmission coefficients t of the input-side optical multiplexer-demultiplexer 62 and the output-side optical multiplexer-demultiplexer 64 of 0.3 (t1), 0.5 (t2), 0.7 (t3), and 0.9 (t4), the trial calculation was performed for 4 points each, 16 points in total of: a power branch ratio of (0.8:0.8)·a phase difference of 0 degree, a power branch ratio of (0.9:0.7)·a phase difference of 45 degrees, a power branch ratio of (0.95:0.6)·a phase difference of 90 degrees, and a power branch ratio of (1:0.5). a phase difference of 150 degrees in the coupling light beam of the first optical coupler 61a and the second optical coupler 61b.

As can be understood from FIG. 12, when the electric field transmission coefficient t of each of the input-side optical multiplexer-demultiplexer 62 and the output-side optical multiplexer-demultiplexer 64 is 0.7 (t3), the power branch ratio of (0.8:0.8). the phase difference of 0 degrees, that is, when the power branch ratio is 0.5 and the coupling light beam of the first optical coupler 61a and the second optical coupler 61b is in the same phase, the gradient of the output indicates the maximum gradient of 0.036 GHz⁻¹.

On the other hand, when the electric field transmission coefficient t is 0.7 (t3) with the power branch ratio of (0.95:0.6). the phase difference of 90 degrees, that is, the power branch ratio is 0.6, and the coupling light beam of the first optical coupler 61a and the second optical coupler 61b has a phase difference of 90 degrees, the gradient of the output is equal to or less than 0.01 GHz⁻¹.

That is, when the electric field transmission coefficient t of each of the input-side optical multiplexer-demultiplexer 62 and the output-side optical multiplexer-demultiplexer 64 is 0.7 (t3), that is, when the power branch ratio of each of the input-side optical multiplexer-demultiplexer 62 and the output-side optical multiplexer-demultiplexer 64 is 0.5, if there is a phase difference of 90 degrees as compared with the case where the coupling light beam of the first optical coupler 61a and the second optical coupler 61b is in the same phase, the gradient of the optical photocurrent by the first optical receiver 65a and the second optical receiver 65b greatly decreases.

On the other hand, when the electric field transmission coefficient t of each of the input-side optical multiplexer-demultiplexer 62 and the output-side optical multiplexer-demultiplexer 64 is 0.9 (t4), it can be seen that the gradient of the photocurrent by the first optical receiver 65a and the second optical receiver 65b is stable at about 0.025 GHz⁻¹ within the range of the assumed mounting deviation in the coupling light beam of the first optical coupler 61a and the second optical coupler 61b and the input-side optical multiplexer-demultiplexer.

That is, within the range of the assumed mounting deviation in the coupling light beam of the first optical coupler 61a and the second optical coupler 61b and the input-side optical multiplexer-demultiplexer, the maximum value of a gradient variation amount indicating a tolerance for the wavelength dependence in the photocurrent by the first optical receiver 65a and the second optical receiver 65b falls within 30%.

In consideration of the control unit 9 located at the subsequent stage of the optical monitor 6, since the control unit 9 processes the photocurrent from the first optical receiver 65a and the photocurrent from the second optical receiver 65b, it is not desirable in design that the gradient of the photocurrent by the first optical receiver 65a and the second optical receiver 65b changes greatly, and it is preferable that the maximum value of the gradient variation amount indicating a tolerance for the wavelength dependence in the photocurrent by the first optical receiver 65a and the second optical receiver 65b be within 30% within the range of the assumed mounting deviation in the coupling light beam of the first optical coupler 61a and the second optical coupler 61b and the input-side optical multiplexer-demultiplexer.

Therefore, it is preferable to design an optical monitor in which the electric field transmission coefficient t of each of the input-side optical multiplexer-demultiplexer 62 and the output-side optical multiplexer-demultiplexer 64 is 0.9, in other words, the power branch ratio of each of the input-side optical multiplexer-demultiplexer 62 and the output-side optical multiplexer-demultiplexer 64 is 0.8 (power branch ratio of 2:8).

In short, within the range of the assumed mounting deviation in the coupling light beam of the first optical coupler 61a and the second optical coupler 61b and the input-side optical multiplexer-demultiplexer, that is, within the range in which the power branch ratio in the coupling light beam of the first optical coupler 61a and the second optical coupler 61b is assumed, even if the coupling efficiency and the coupling phase of the backward laser beam Lb of the semiconductor laser 5 to the first optical coupler 61a and the second optical coupler 61b change, the maximum value of the gradient variation amount indicating the tolerance for the wavelength dependence in the photocurrent from the first optical receiver 65a and the photocurrent from the second optical receiver 65b is preferably within 30%.

As described above, in the optical module according to the first embodiment, the optical monitor 6 includes the first optical coupler 61a that receives the laser beam from the semiconductor laser 5, the second optical coupler 61b that receives the laser beam from the semiconductor laser 5, the first optical receiver 65a that outputs the first monitor value, and the second optical receiver 65b that outputs the second monitor value, and the optical interferometer is constituted in such a manner that the first path from the first optical coupler 61a to the first optical receiver and the second path from the second optical coupler to the second optical receiver are asymmetric, whereby the optical power monitor value Ip and the wavelength monitor value Iλ/Ip can be obtained by the first monitor value and the second monitor value, and the laser beam from the semiconductor laser 5 can be controlled to have a precise single wavelength.

In the optical module according to the first embodiment, since the first optical coupler 61a and the second optical coupler 61b are used as compared with that using one assumed optical coupler, a double effect is obtained, and since the wavelength monitor value Iλ is obtained by the difference value between the first monitor value and the second monitor value, a double effect is obtained, and as a result, the optical monitor 6 having a sensitivity of 4 times is obtained.

In the optical module according to the first embodiment, the optical monitor 6 includes the input-side optical multiplexer-demultiplexer 62 including the first optical waveguide 62a and the second optical waveguide 62b, the first asymmetric arm 63a including the optical waveguide, the second asymmetric arm 63b including the optical waveguide whose length is different from a length of the optical waveguide constituting the first asymmetric arm 63a, and the output-side optical multiplexer-demultiplexer 64 including the third optical waveguide 64a and the fourth optical waveguide 64b, so that the optical monitor 6 can be constituted by a planar waveguide optical monitor, the number of components is small, and downsizing can be achieved.

Since the optical module according to the first embodiment is an optical multiplexer-demultiplexer in which the power branch ratio of each of the input-side optical multiplexer-demultiplexer 62 and the output-side optical multiplexer-demultiplexer 64 is 0.8, the gradient of the photocurrent by the first optical receiver 65a and the gradient of the photocurrent by the second optical receiver 65b are stable within the range of the assumed mounting deviation in the coupling light beam with the input-side optical multiplexer-demultiplexer of the first optical coupler 61a and the second optical coupler 61b, and the processing of the photocurrent in the control unit 9 located at the subsequent stage of the optical monitor 6 is easy.

In particular, when the maximum value of the gradient variation amount indicating the tolerance for the wavelength dependence of the photocurrent indicating the first monitor value output from the first optical receiver 65a and the photocurrent indicating the second monitor value output from the second optical receiver 65b is within 30%, the processing of the photocurrent in the control unit 9 is easy.

In the optical module according to the first embodiment, since the semiconductor laser 5, the optical monitor 6, the temperature adjuster 2, and the base 3 are arranged in the space formed by the stem 1 and the cap 7, the number of lead pins for the semiconductor laser 5, the optical monitor 6, and the temperature adjuster 2 can be reduced.

### Second Embodiment

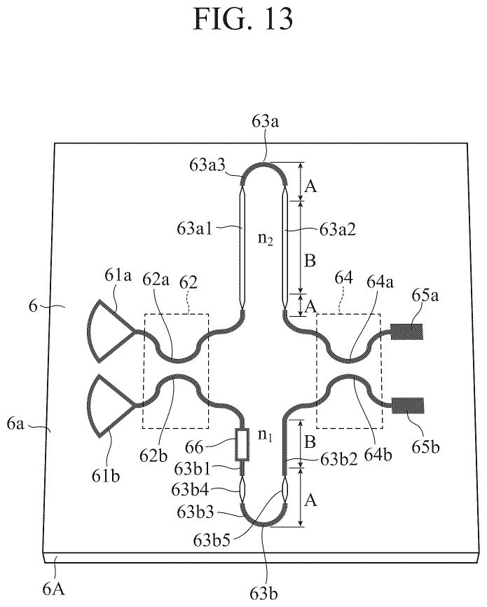

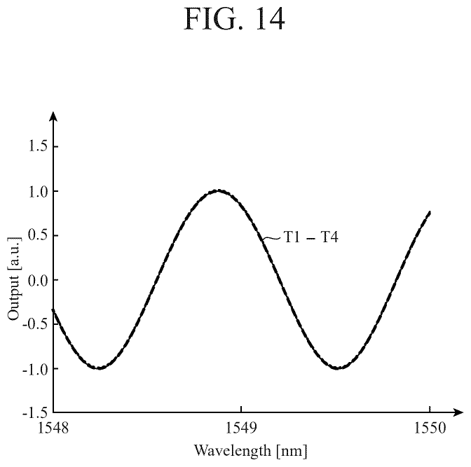

An optical module according to a second embodiment will be described with reference to FIGS. 13 and 14.

The optical module according to the second embodiment is different from the optical module according to the first embodiment in configuration of the optical monitor 6, and is the same as or similar to the optical module according to the first embodiment in other points.

That is, in the optical module according to the first embodiment, in a case where the optical monitor 6 is constituted by a planar waveguide optical monitor using a silicon photonics chip, the first asymmetric arm 63a and the second asymmetric arm 63b are constituted by waveguides having the same group refractive index, specifically, silicon waveguides.

On the other hand, the optical module according to the second embodiment is different from the optical module according to the first embodiment in that, in a case where the optical monitor 6 is constituted by a planar waveguide optical monitor using a silicon photonics chip, the first asymmetric arm 63a and the second asymmetric arm 63b are constituted by optical waveguides having a common portion and a non-common portion, the non-common portion of the first asymmetric arm 63a is constituted by an optical waveguide having a first group refractive index, and the non-common portion of the second asymmetric arm 63b is constituted by an optical waveguide having a second group refractive index different from the first group refractive index, and the other points are the same as those of the optical module according to the first embodiment.

Note that, in FIG. 13, the same reference signs as those in FIG. 5 denote the same or corresponding parts.

Note that the overall configuration of the optical module is the same as that in FIGS. 1 to 3 illustrating the first embodiment, and thus is omitted.

Hereinafter, a description will be given focusing on the optical monitor 6 in a case where the optical monitor 6 is constituted by a planar waveguide optical monitor using a silicon photonics chip, in particular, the first asymmetric arm 63a and the second asymmetric arm 63b.

The optical monitor 6 includes a first optical coupler 61a, a second optical coupler 61b, an input-side optical multiplexer-demultiplexer 62, a first asymmetric arm 63a, a second asymmetric arm 63b, an output-side optical multiplexer-demultiplexer 64, a first optical receiver 65a, a second optical receiver 65b, and a phase adjuster 66.

The output-side optical multiplexer-demultiplexer 64, the first optical receiver 65a, and the second optical receiver 65b function as an interference measurement system for viewing wavelength dependence similarly to the output-side optical multiplexer-demultiplexer 64, the first optical receiver 65a, and the second optical receiver 65b in the first embodiment.

The output-side optical multiplexer-demultiplexer 64 is an optical circuit constituting an interference measurement system by the first optical receiver 65a and the second optical receiver 65b.

The optical monitor 6 is, for example, a planar waveguide optical monitor using a silicon photonics chip formed by integrating the first optical coupler 61a, the second optical coupler 61b, the input-side optical multiplexer-demultiplexer 62, the first asymmetric arm 63a, the second asymmetric arm 63b, the output-side optical multiplexer-demultiplexer 64, the first optical receiver 65a, and the second optical receiver 65b on a flat surface of a silicon (Si) substrate 6A.

The first optical coupler 61a, the second optical coupler 61b, the input-side optical multiplexer-demultiplexer 62, the output-side optical multiplexer-demultiplexer 64, the first optical receiver 65a, the second optical receiver 65b, and the phase adjuster 66 are the same as the first optical coupler 61a, the second optical coupler 61b, the input-side optical multiplexer-demultiplexer 62, the output-side optical multiplexer-demultiplexer 64, the first optical receiver 65a, the second optical receiver 65b, and the phase adjuster 66 constituting the optical monitor 6, respectively, in the optical module according to the first embodiment.

An input node of the first asymmetric arm 63a is optically connected to the second port of the input-side optical multiplexer-demultiplexer 62, and an output node of the first asymmetric arm 63a is optically connected to the first port of the output-side optical multiplexer-demultiplexer.

An input node of the second asymmetric arm 63b is optically connected to the fourth port of the input-side optical multiplexer-demultiplexer 62, and an output node of the second asymmetric arm 63b is optically connected to the third port of the output-side optical multiplexer-demultiplexer.

As illustrated in FIG. 13, each of the first asymmetric arm 63a and the second asymmetric arm 63b includes an optical waveguide having a common portion A and a non-common portion B.

The first asymmetric arm 63a includes silicon nitride waveguides 63a1 and 63a2 and a silicon waveguide 63a3.

The temperature dependence of the group refractive index n₂ in the silicon nitride waveguide is different from the temperature dependence of the group refractive index n₁ (described as no in the first embodiment) in the silicon waveguide.

The first asymmetric arm 63a is U-shaped. Note that the shape is not limited to the U-shape.

The silicon nitride waveguide 63a1 and the silicon nitride waveguide 63a2 are positioned at a U-shaped leg, and are disposed to face each other.

A length (physical length) of the silicon nitride waveguide 63a1 and a length (physical length) of the silicon nitride waveguide 63a2 are the same lengths (physical lengths).

One end of the silicon nitride waveguide 63a1 is optically connected to the second port of the input-side optical multiplexer-demultiplexer 62 via a silicon waveguide.

The other end of the silicon nitride waveguide 63a2 is optically connected to the first port of the output-side optical multiplexer-demultiplexer 64 via a silicon waveguide.

The silicon waveguide 63a3 is optically connected between the other end of the silicon nitride waveguide 63a1 and one end of the silicon nitride waveguide 63a2, and is located at a folded back portion in the first asymmetric arm 63a.

The first asymmetric arm 63a is a light propagation path that is optically connected from the input node to the silicon nitride waveguide 63a1, the silicon waveguide 63a3, and the silicon nitride waveguide 63a2 in this order, and reaches the output node.

The first asymmetric arm 63a is bilaterally symmetrical.

The silicon nitride waveguide 63a1 and the silicon nitride waveguide 63a2 each have a common portion A and a non-common portion B.

In the silicon nitride waveguide 63a1, as illustrated in FIG. 13, the common portion A includes a portion on a side optically connected to the silicon waveguide 63a3 and a portion on a side optically connected to the second port of the input-side optical multiplexer-demultiplexer 62, and the non-common portion B is a remaining portion of the silicon nitride waveguide 63a1, that is, a central portion.

Similarly to the common portion A and the non-common portion B in the silicon nitride waveguide 63a1, as the common portion A and the non-common portion B in the silicon nitride waveguide 63a2, both end portions are the common portion A, and the central portion is the non-common portion B.

A length (physical length) of the non-common portion B in the silicon nitride waveguide 63a1 and a length (physical length) of the non-common portion B in the silicon nitride waveguide 63a2 are each (L+ΔL)/2.

Therefore, the non-common portion B in the first asymmetric arm 63a is constituted by a silicon nitride waveguide, and the length (physical length) is (L+ΔL).

The silicon waveguide 63a3 is a common portion A.

The second asymmetric arm 63b includes silicon waveguides 63b1 to 63b3 and silicon nitride waveguides 63b4 and 63b5.

The second asymmetric arm 63b is U-shaped. Note that the shape is not limited to the U-shape.

The silicon waveguide 63b1 and the silicon waveguide 63b2 are positioned at a U-shaped leg, and are arranged to face each other.

A length (physical length) of the silicon waveguide 63b1 and a length (physical length) of the silicon waveguide 63b2 are the same lengths (physical lengths).

One end of the silicon waveguide 63b1 is optically connected to the fourth port of the input-side optical multiplexer-demultiplexer 62 via a silicon waveguide. Note that, since the silicon waveguide 63b1 and the silicon waveguide that is the second optical waveguide 62b of the input-side optical multiplexer-demultiplexer 62 are continuously formed, the one end of the silicon waveguide 63b1 and the fourth port of the input-side optical multiplexer-demultiplexer 62 do not physically exist.

The other end of the silicon waveguide 63b2 is optically connected to the third port of the output-side optical multiplexer-demultiplexer 64 via a silicon waveguide. Since the silicon waveguide 63b2 and the silicon waveguide that is the fourth optical waveguide 64b of the output-side optical multiplexer-demultiplexer 64 are continuously formed, the other end of the silicon waveguide 63b2 and the third port of the output-side optical multiplexer-demultiplexer 64 do not physically exist.

The silicon nitride waveguide 63b4 and the silicon nitride waveguide 63b5 are positioned at a U-shaped leg, and are arranged to face each other.

A length (physical length) of the silicon nitride waveguide 63b4 and a length (physical length) of the silicon nitride waveguide 63b5 are the same lengths (physical lengths).

One end of the silicon nitride waveguide 63b4 is optically connected to the other end of the silicon waveguide 63b1.

The other end of the silicon nitride waveguide 63b5 is optically connected to one end of the silicon waveguide 63b2.

The silicon waveguide 63b3 is optically connected between the other end of the silicon nitride waveguide 63b4 and one end of the silicon nitride waveguide 63b5, and is located at a folded back portion in the second asymmetric arm 63b.

The second asymmetric arm 63b is a light propagation path that is optically connected from the input node to the silicon waveguide 63b1, the silicon nitride waveguide 63b4, the silicon waveguide 63b3, the silicon nitride waveguide 63b5, and the silicon waveguide 63b2 in this order, and reaches the output node.

The second asymmetric arm 63b is bilaterally symmetrical.

As illustrated in FIG. 13, the silicon nitride waveguide 63b4, the silicon nitride waveguide 63b5, and the silicon waveguide 63b3 are a common portion A for the first asymmetric arm 63a.

That is, the length of the silicon nitride waveguide 63b4 in the second asymmetric arm 63b is the same as the length of a portion of the silicon nitride waveguide 63a1 in the first asymmetric arm 63a, the length of the silicon nitride waveguide 63b5 in the second asymmetric arm 63b is the same as the length of a portion of the silicon nitride waveguide 63a2 in the first asymmetric arm 63a, and the length of the silicon waveguide 63b3 in the second asymmetric arm 63b is the same as the length of the silicon waveguide 63a3 in the first asymmetric arm 63a.

The length (physical length) of L/2 in each of the silicon waveguide 63b1 and the silicon waveguide 63b2 is defined as a non-common portion B for the first asymmetric arm 63a.

That is, in the second asymmetric arm 63b, a portion of the silicon waveguide 63b1 and a portion of the silicon waveguide 63b2 excluding the common portion A located at the U-shaped folded back portion are non-common portions B.

A length (physical length) of the non-common portion B in the silicon waveguide 63b1 and a length (physical length) of the non-common portion B in the silicon waveguide 63b2 are each L/2.

Therefore, the non-common portion B in the second asymmetric arm 63b is constituted by a silicon waveguide, and the length (physical length) is L.

The length (physical length) of the non-common portion B in the first asymmetric arm 63a is longer by a length ΔL than the length (physical length) of the non-common portion B in the second asymmetric arm 63b.

The first path is a propagation path of light from the first port of the input-side optical multiplexer-demultiplexer 62 to the second port of the output-side optical multiplexer-demultiplexer 64 via the input-side optical multiplexer-demultiplexer 62, the first asymmetric arm 63a including the silicon nitride waveguides 63a1 and 63a2, and the silicon waveguide 63a3, and the output-side optical multiplexer-demultiplexer 64 in a case where the optical monitor 6 is constituted by a planar waveguide optical monitor using a silicon photonics chip.

The second path is a propagation path of light from the third port of the input-side optical multiplexer-demultiplexer 62 to the fourth port of the output-side optical multiplexer-demultiplexer 64 via the input-side optical multiplexer-demultiplexer 62, the second asymmetric arm 63b including the silicon waveguides 63b1 to 63b3, and the silicon nitride waveguides 63b4 and 63b5, and the output-side optical multiplexer-demultiplexer 64.

Next, how to determine the length (physical length) of the non-common portion B of the first asymmetric arm 63a and the length (physical length) of the non-common portion B of the second asymmetric arm 63b will be described.

Since the common portion A of the first asymmetric arm 63a and the common portion A of the second asymmetric arm 63b have the same length and shape, the phase difference between the common portion A of the first asymmetric arm 63a and the common portion A of the second asymmetric arm 63b does not change even when the temperature changes.

The non-common portion B of the first asymmetric arm 63a and the non-common portion B of the second asymmetric arm 63b are made of different materials from the silicon nitride waveguide and the silicon waveguide, and have different lengths (L+λL) and L.

Therefore, it is sufficient if the phase change due to the temperature is considered for the non-common portion B of the first asymmetric arm 63a and the non-common portion B of the second asymmetric arm 63b.

The linear expansion coefficient of the substrate in the planar waveguide optical monitor is α.

Since the physical length L and the physical length ΔL need to be positive values, the following Expression (3) is satisfied.

$$d {n}_{1} / dT + {n}_{1} α > d {n}_{2} / dT + {n}_{2} α \qquad ( 3 )$$

The phase difference θ between the first monitor value (photocurrent from the first optical receiver 65a) and the second monitor value (photocurrent from the second optical receiver 65b) on the optical monitor 6 can be expressed by the following Expression (4).

$${n}_{2} ( L + Δ L ) - {n}_{1} \cdot L = m \cdot λ = ( λ / 2 π ) \cdot θ \qquad ( 4 )$$

In the above Expressions (3) and (4), n₂ is a group refractive index in the silicon nitride waveguide, n₁ is a group refractive index in the silicon waveguide, (L+ΔL) is a length (physical length) of the non-common portion B of the first asymmetric arm 63a, L is a length (physical length) of the non-common portion B of the second asymmetric arm 63b, λ is a wavelength of the backward laser beam Lb, m is a coefficient connecting the wavelength λ and the optical path length nL.

In the above Expression (4), n₁, n₂, L, and ΔL are determined in such a manner that the temperature derivative of the above Expression (4) is always 0, whereby the temperature does not depend on the temperature.

That is, in the above Expression (4), the following Expression (5) is obtained by subjecting the left side to temperature differentiation and solving the above Expression (4) with the right side set to 0.

The following Expression (5) is obtained in such a manner that the temperature derivative of the above Expression (4) is always 0, and is a relational expression independent of the environmental temperature and the operating temperature.

$$L = {( \frac{\frac{{dn}_{1}}{dT} + {n}_{1} α}{\frac{{dn}_{2}}{dT} + {n}_{2} α} - 1 )}^{- 1} \cdot Δ L \qquad ( 5 )$$

Since the relationship between L and ΔL satisfies the above Expression (5), if the backward laser beam Lb from the semiconductor laser 5 does not change, the wavelength monitor value Iλ/Ip obtained from the first monitor value obtained from the first optical receiver 65a and the second monitor value obtained from the second optical receiver 65b does not have temperature dependence, and a highly accurate wavelength monitor value Iλ/Ip that does not depend on the environmental temperature and the operating temperature can be obtained.

Here, the group refractive index n₂ can be determined by the group refractive index of the silicon nitride waveguide, and the group refractive index n₁ can be determined by the group refractive index of the silicon waveguide.

That is, inside of ( ) in the above Expression (5) can be determined.

Note that the physical length ΔL can be determined by FSR design of the Mach-Zehnder interferometer output.

Therefore, the physical length L can be obtained by the above Expression (5).

Note that, when it is desired to increase the gradient of the photocurrent from the first optical receiver 65a and the gradient of the photocurrent from the second optical receiver 65b, ΔL may be increased to reduce the FSR by the FSR design, and when it is desired to reduce the gradient, ΔL may be decreased to increase the FSR.

FIG. 14 illustrates a trial calculation result of temperature characteristics of the optical monitor 6 when the temperature of the optical monitor 6 is 20 degrees, 30 degrees, 40 degrees, and 50 degrees.

In FIG. 14, the horizontal axis represents the wavelength of the backward laser beam Lb, and the vertical axis represents the output from the optical receiver.

Temperature characteristics when the waveform T1 is 20 degrees, temperature characteristics when the waveform T2 is 30 degrees, temperature characteristics when the waveform T3 is 40 degrees, and temperature characteristics when the waveform T4 is 50 degrees are illustrated.

As is clear from FIG. 14, it can be understood that the waveform T1 to the waveform T4 overlap, and the optical monitor 6 that can obtain the first monitor value and the second monitor value having no temperature dependence can be implemented.

In the optical monitor 6 described above, since the first asymmetric arm 63a includes the silicon nitride waveguides 63a1 and 63a2 and the silicon waveguide 63a3, and the second asymmetric arm 63b includes the silicon waveguides 63b1 to 63b3 and the silicon nitride waveguides 63b4 and 63b5, the first asymmetric arm 63a and the second asymmetric arm 63b have the same number of connection points between waveguides having different characteristics, that is, in the first asymmetric arm 63a, the silicon nitride waveguides 63a1 and 63a2 have the same number of connection points with the silicon waveguides in total of four, and in the second asymmetric arm 63b, the silicon nitride waveguides 63b4 and 63b5 have the same number of connection points with the silicon waveguides in total of four, the difference in propagation loss between the first asymmetric arm 63a and the second asymmetric arm 63b can be minimized.

Note that the second asymmetric arm 63b may be constituted by a silicon waveguide alone from the input node to the output node.

In this case, both the common portion A of the first asymmetric arm 63a and the common portion A of the second asymmetric arm 63b may be constituted by a silicon waveguide, the non-common portion B of the first asymmetric arm 63a only needs to be constituted by a silicon nitride waveguide, and the non-common portion B of the second asymmetric arm 63b only needs to be constituted by a silicon waveguide.

Also in this case, since the relationship between L and ΔL satisfies the above Expression (5), the optical monitor 6 can be implemented in which, if the backward laser beam Lb from the semiconductor laser 5 does not change, the wavelength monitor value Iλ/Ip obtained from the first monitor value obtained from the first optical receiver 65a and the second monitor value obtained from the second optical receiver 65b has no temperature dependence.

Note that the relationship between the first asymmetric arm 63a and the second asymmetric arm 63b only needs to be a relationship in which the lengths of the optical waveguides are different and the group refractive indexes are different in the non-common portion B, and is not limited to the planar waveguide optical monitor using the silicon photonics chip, and may be a planar waveguide optical monitor using an indium phosphorus substrate or a glass substrate which is a compound semiconductor.

The operation of the optical module according to the second embodiment is also substantially the same as the operation of the optical module according to the first embodiment.

The differences are only the following points, and description other than the differences will be omitted.

That is, the laser beam from the first optical coupler 61a that has received the backward laser beam Lb of the semiconductor laser 5 enters the first optical waveguide 62a constituting the input-side optical multiplexer-demultiplexer 62 from the first port of the input-side optical multiplexer-demultiplexer 62.

On the other hand, the laser beam from the second optical coupler 61b that has received the backward laser beam Lb of the semiconductor laser 5 enters the second optical waveguide 62b constituting the input-side optical multiplexer-demultiplexer 62 from the third port of the input-side optical multiplexer-demultiplexer 62.

The laser beam from the first optical coupler 61a and the laser beam from the second optical coupler 61b incident on the input-side optical multiplexer-demultiplexer 62 are demultiplexed and interfered by the input-side optical multiplexer-demultiplexer 62, and propagated from the second port of the input-side optical multiplexer-demultiplexer 62 to the first asymmetric arm 63a and from the fourth port of the input-side optical multiplexer-demultiplexer 62 to the second asymmetric arm 63b.

The laser beam propagated through the first asymmetric arm 63a is propagated from the first port of the output-side optical multiplexer-demultiplexer 64 to the third optical waveguide 64a constituting the output-side optical multiplexer-demultiplexer 64.

The laser beam propagated through the second asymmetric arm 63b is propagated from the third port of the output-side optical multiplexer-demultiplexer 64 to the fourth optical waveguide 64b constituting the output-side optical multiplexer-demultiplexer 64.

Each of the laser beam propagated through the first asymmetric arm 63a and the laser beam propagated through the second asymmetric arm 63b and propagated to the output-side optical multiplexer-demultiplexer 64 is demultiplexed and interfered by the output-side optical multiplexer-demultiplexer 64, is incident on the first optical receiver 65a from the second port of the output-side optical multiplexer-demultiplexer 64, and is incident on the second optical receiver 65b from the fourth port of the output-side optical multiplexer-demultiplexer 64.

The laser beam incident on the first optical receiver 65a is photoelectrically converted by the first optical receiver 65a, and a photocurrent indicating the first monitor value is output to the control unit 9.

The laser beam incident on the second optical receiver 65b is photoelectrically converted by the second optical receiver 65b, and a photocurrent indicating the second monitor value is output to the control unit 9.

The wavelength monitor value Iλ/Ip calculated by the control unit 9 does not depend on the environmental temperature and the operating temperature due to the operation of the first asymmetric arm 63a and the second asymmetric arm 63b.

In the optical module according to the second embodiment, as a result of trial calculation, an oscillation wavelength from the semiconductor laser 5 fluctuates to 0.05 nm or less within a temperature change range in which the shift amount in the wavelength direction of the wavelength dependence of the wavelength dependence of the wavelength monitor value, which is the ratio between the optical power monitor value and the wavelength monitor value calculated from the photocurrent obtained from the first optical receiver 65a and the photocurrent obtained from the second optical receiver 65b, is 100 degrees by performing the wavelength locker step.

That is, in the temperature change range of 100 degrees, the oscillation wavelength from the semiconductor laser 5 fluctuates to 0.05 nm or less, and the optical module according to the second embodiment has very low temperature dependence.

The optical module according to the second embodiment can obtain an oscillation wavelength of 0.1 nm or less from the semiconductor laser 5 within a temperature change range in which the shift amount in the wavelength direction of the wavelength monitor value Iλ/Ip, which is the ratio between the optical power monitor value Ip calculated from the photocurrent indicating the first monitor value output from the first optical receiver 65a and the photocurrent indicating the second monitor value output from the second optical receiver 65b and the wavelength monitor value Iλ, is 100 degrees, and can perform precise control on the laser beam from the semiconductor laser 5.

As described above, similarly to the optical module according to the first embodiment, the optical module according to the second embodiment can be controlled to have a precise single wavelength with respect to the laser beam from the semiconductor laser 5, the number of parts is small, and downsizing can be achieved.

Further, in the optical module according to the second embodiment, in the optical monitor 6, the respective lengths of the optical waveguides in the non-common portion B in the first asymmetric arm 63a and the non-common portion B in the second asymmetric arm 63b are different from each other, and the group refractive indexes are different from each other, so that, by appropriately selecting the lengths and the group refractive indexes of the non-common portions B, the wavelength monitor value Iλ/Ip obtained from the first monitor value obtained from the first optical receiver 65a and the second monitor value obtained from the second optical receiver 65b can be set to the wavelength monitor value having no temperature dependence.

### Third Embodiment

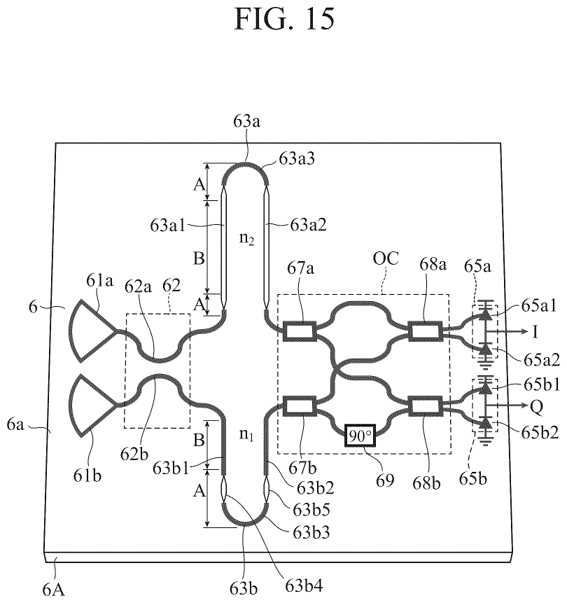

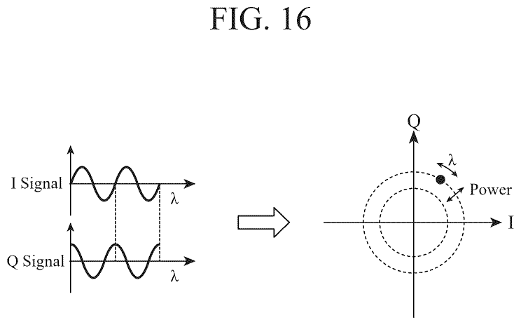

An optical module according to a third embodiment will be described with reference to FIGS. 15 and 16.

The optical module according to the third embodiment is different from the optical module according to the second embodiment in configuration of the optical monitor 6, and is the same as or similar to the optical module according to the first embodiment in other points.

That is, in the optical module according to the second embodiment, in a case where the optical monitor 6 is constituted by a planar waveguide optical monitor using a silicon photonics chip, the optical circuits after the first asymmetric arm 63a and the second asymmetric arm 63b are configured to include the output-side optical multiplexer-demultiplexer 64, the first optical receiver 65a, and the second optical receiver 65b, and further include the phase adjuster 66.

On the other hand, the optical module according to the third embodiment is different from the optical module according to the second embodiment in that the optical circuit after the first asymmetric arm 63a and the second asymmetric arm 63b is configured to include a 90-degree hybrid configuration optical circuit OC, the first light receiving unit 65a, and the second light receiving unit 65b and is configured not to include the phase adjuster 66 in a case where the optical monitor 6 is configured by a planar waveguide optical monitor using a silicon photonics chip, and is the same as the optical module according to the second embodiment in other points.

That is, while the output-side optical multiplexer-demultiplexer 64, the first optical receiver 65a, and the second optical receiver 65b function as an interference measurement system for viewing wavelength dependence in the second embodiment, the 90-degree hybrid configuration optical circuit OC, the first optical receiver 65a, and the second optical receiver 65b function as an interference measurement system for viewing wavelength dependence in the third embodiment is different, and the third embodiment is similar to the second embodiment in other points.

The 90-degree hybrid configuration optical circuit OC is an optical circuit constituting an interference measurement system by the first optical receiver 65a and the second optical receiver 65b.

Note that, in FIG. 15, the same reference signs as those in FIG. 13 denote the same or corresponding parts.

Note that the overall configuration of the optical module is the same as that of FIGS. 1 to 3 illustrating the first embodiment similarly to the second embodiment, and thus is omitted.

Hereinafter, an optical monitor 6 in a case where the optical monitor 6 is constituted by a planar waveguide optical monitor using a silicon photonics chip, in particular, an optical circuit after the first asymmetric arm 63a and the second asymmetric arm 63b, that is, an optical circuit functioning as an interference measurement system for viewing wavelength dependence will be mainly described.

The optical monitor 6 includes a first optical coupler 61a, a second optical coupler 61b, an input-side optical multiplexer-demultiplexer 62, a first asymmetric arm 63a, a second asymmetric arm 63b, a 90-degree hybrid configuration optical circuit OC, a first light receiving unit 65a, and a second light receiving unit 65b.

The optical monitor 6 is, for example, a planar waveguide optical monitor using a silicon photonics chip formed by integrating the first optical coupler 61a, the second optical coupler 61b, the input-side optical multiplexer-demultiplexer 62, the first asymmetric arm 63a, the second asymmetric arm 63b, the 90-degree hybrid configuration optical circuit OC, the first light receiving unit 65a, and the second light receiving unit 65b on a flat surface of a silicon substrate 6A.

The first optical coupler 61a, the second optical coupler 61b, the input-side optical multiplexer-demultiplexer 62, the first asymmetric arm 63a, and the second asymmetric arm 63b are the same as the first optical coupler 61a, the second optical coupler 61b, the input-side optical multiplexer-demultiplexer 62, the first asymmetric arm 63a, and the second asymmetric arm 63b constituting the optical monitor 6 in the optical module according to the second embodiment.

The 90-degree hybrid configuration optical circuit OC includes a first input node, a second input node, a first output node, and a second output node, where the first input node is optically connected to the output node of the first asymmetric arm 63a, the second input node is optically connected to the output node of the second asymmetric arm 63b, an I optical output is output to the first output node, and a Q optical output is output to the second output node.

In this example, the I light output includes a first I output light and a second I output light.

In this example, the Q light output includes a first Q output light and a second Q output light.

The first light receiving unit 65a receives the I optical output from the first output node of the 90-degree hybrid configuration optical circuit OP, and outputs a first monitor value that is an I signal illustrated in FIG. 16.

In the I signal illustrated in FIG. 16, the horizontal axis represents the wavelength of the backward laser beam Lb, and the vertical axis represents the output from the first light receiving unit 65a.

The first light receiving unit 65a includes a first I optical receiver 65a1 and a second I optical receiver 65a2 connected in series between a power supply potential node for the light receiving unit and a ground node. In this case, the first optical receiver 65a including the first I optical receiver 65a1 and the second I optical receiver 65a2 is also included as a first optical receiver.

The first I optical receiver 65a1 receives a first I output light from the 90-degree hybrid configuration optical circuit OC.

The second I optical receiver 65a2 receives a second I output light from the 90-degree hybrid configuration optical circuit OC.

The first monitor value that is an I signal is output to a connection point between the first I optical receiver 65a1 and the second I optical receiver 65a2.

The second light receiving unit 65b receives a Q light output from the second output node of the 90-degree hybrid configuration optical circuit OP, and outputs a second monitor value that is a Q signal illustrated in FIG. 16.

In the Q signal illustrated in FIG. 16, the horizontal axis represents the wavelength of the backward laser beam Lb, and the vertical axis represents the output from the second light receiving unit 65b.

There is a phase difference of 90 degrees between the Q signal and the I signal.

The second light receiving unit 65b includes a first Q optical receiver 65b1 and a second Q optical receiver 65b2 connected in series between the power supply potential node for the light receiving unit and the ground node. In this case, the second light receiving unit 65b including the first Q optical receiver 65b1 and the second Q optical receiver 65b2 is also included as a second optical receiver.

The first Q optical receiver 65b1 receives the first Q output light from the 90-degree hybrid configuration optical circuit OC.

The second Q optical receiver 65b2 receives the second Q output light from the 90-degree hybrid configuration optical circuit OC.

The second monitor value that is a Q signal is output to a connection point between the first Q optical receiver 65b1 and the second Q optical receiver 65b2.

The 90-degree hybrid configuration optical circuit OC includes a first 1×2 optical multiplexer-demultiplexer 67a, a second 1×2 optical multiplexer-demultiplexer 67b, a first 2×2 optical multiplexer-demultiplexer 68a, a second 2×2 optical multiplexer-demultiplexer 68b, and a 90-degree delayer 69.

The first 1×2 optical multiplexer-demultiplexer 67a has a first port to a third port.

The first port of the first 1×2 optical multiplexer-demultiplexer 67a is optically connected to the output node of the first asymmetric arm 63a.

The first 1×2 optical multiplexer-demultiplexer 67a demultiplexes the optical output from the first asymmetric arm 63a into two optical outputs.

The first 1×2 optical multiplexer-demultiplexer 67a is, for example, any of a directional coupler, an MMI waveguide, or a Y-branch waveguide. In this example, an MMI waveguide is used as the first 1×2 optical multiplexer-demultiplexer 67a.

Note that the first port of the first 1×2 optical multiplexer-demultiplexer 67a and the output node of the first asymmetric arm 63a are not physically configured separately, but are a connection point of silicon waveguides continuously forming the first port of the first 1×2 optical multiplexer-demultiplexer 67a and the first asymmetric arm 63a.

The second 1×2 optical multiplexer-demultiplexer 67b has a first port to a third port.

The first port of the second 1×2 optical multiplexer-demultiplexer 67b is optically connected to the output node of the second asymmetric arm 63b.

The second 1×2 optical multiplexer-demultiplexer 67b demultiplexes the optical output from the second asymmetric arm 63b into two optical outputs.

The second 1×2 optical multiplexer-demultiplexer 67b is, for example, any of a directional coupler, an MMI waveguide, or a Y-branch waveguide. In this example, an MMI waveguide is used as the second 1×2 optical multiplexer-demultiplexer 67b.

Note that the first port of the second 1×2 optical multiplexer-demultiplexer 67b and the output node of the second asymmetric arm 63b are not physically configured separately, but are a connection point of silicon waveguides continuously forming the first port of the second 1×2 optical multiplexer-demultiplexer 67b and the second asymmetric arm 63b.

The 90-degree delayer 69 delays the input optical output by 90 degrees, that is, changes the phase by 90 degrees and outputs the optical output.

An input node of the 90-degree delayer 69 is optically connected to the third port of the second 1×2 optical multiplexer-demultiplexer 67b.

The 90-degree delayer 69 includes optical waveguides.

Note that the input node of the 90-degree delayer 69 and the third port of the second 1×2 optical multiplexer-demultiplexer 67b are not physically configured separately, but are a connection point of silicon waveguides continuously forming optical waveguides constituting the 90-degree delayer 69 and the other output side of the second 1×2 optical multiplexer-demultiplexer 67b.

The first 2×2 optical multiplexer-demultiplexer 68a has a first port to a fourth port, and has a fifth optical waveguide connecting the first port and the second port and a sixth optical waveguide connecting the third port and the fourth port.

In the first 2×2 optical multiplexer-demultiplexer 68a, the first port is optically connected to the second port of the first 1×2 optical multiplexer-demultiplexer 67a, and the third port is optically connected to the second port of the second 1×2 optical multiplexer-demultiplexer 67b.

The fifth optical waveguide and the sixth optical waveguide in the first 2×2 optical multiplexer-demultiplexer 68a are silicon waveguides.

The length of the fifth optical waveguide and the length of the sixth optical waveguide are the same.

The first 2×2 optical multiplexer-demultiplexer 68a is an asymmetric optical multiplexer-demultiplexer, and in this example, the power branch ratio is set to 0.8, for example. In other words, the power branch ratio for the fifth optical waveguide and the sixth optical waveguide is 2:8.

Note that the first port of the first 2×2 optical multiplexer-demultiplexer 68a and the second port of the first 1×2 optical multiplexer-demultiplexer 67a are not physically configured separately, but are a connection point of silicon waveguides continuously forming the fifth optical waveguide constituting the first 2×2 optical multiplexer-demultiplexer 68a and an optical waveguide constituting one output side of the first 1×2 optical multiplexer-demultiplexer 67a.

Further, the third port of the first 2×2 optical multiplexer-demultiplexer 68a and the second port of the second 2×2 optical multiplexer-demultiplexer 67b are not physically configured separately, but are a connection point of silicon waveguides continuously forming the sixth optical waveguide constituting the second 2×2 optical multiplexer-demultiplexer 67b and an optical waveguide constituting one output side of the second 1×2 optical multiplexer-demultiplexer 67a.

The first 2×2 optical multiplexer-demultiplexer 68a is, for example, any of a directional coupler, an MMI waveguide, or a Y-branch waveguide. In this example, an MMI waveguide is used as the first 2×2 optical multiplexer-demultiplexer 68a.

The second 2×2 optical multiplexer-demultiplexer 68b has a first port to a fourth port, and has a seventh optical waveguide connecting the first port and the second port and an eighth optical waveguide connecting the third port and the fourth port.

In the second 2×2 optical multiplexer-demultiplexer 68b, the first port is optically connected to the third port of the first 1×2 optical multiplexer-demultiplexer 67a, and the third port is optically connected to the output node of the 90-degree delayer 69.

The seventh optical waveguide and the eighth optical waveguide in the second 2×2 optical multiplexer-demultiplexer 68b are silicon waveguides.

The length of the seventh optical waveguide and the length of the eighth optical waveguide are the same.

The second 2×2 optical multiplexer-demultiplexer 68b is an asymmetric optical multiplexer-demultiplexer, and in this example, the power branch ratio is set to 0.8, for example. In other words, the power branch ratio for the seventh optical waveguide and the eighth optical waveguide is 2:8.

Note that the first port of the second 2×2 optical multiplexer-demultiplexer 68b and the third port of the first 1×2 optical multiplexer-demultiplexer 67a are not physically configured separately, but are a connection point of silicon waveguides continuously forming the seventh optical waveguide constituting the second 2×2 optical multiplexer-demultiplexer 68b and an optical waveguide constituting the other output side of the first 1×2 optical multiplexer-demultiplexer 67a.

Further, the third port of the second 2×2 optical multiplexer-demultiplexer 68b and the output node of the 90-degree delayer 69 are not physically configured separately, but are a connection point of silicon waveguides continuously forming the eighth optical waveguide constituting the second 2×2 optical multiplexer-demultiplexer 68b and the optical waveguide constituting the 90-degree delayer 69.

The second 2×2 optical multiplexer-demultiplexer 68b is, for example, any of a directional coupler, an MMI waveguide, or a Y-branch waveguide. In this example, an MMI waveguide is used as the second 2×2 optical multiplexer-demultiplexer 68b.

In the first I optical receiver 65a1 constituting the first light receiving unit 65a, an anode electrode is connected to the power supply potential node for the light receiving unit, and a cathode electrode is connected to a first output end of the optical monitor 6 that outputs the first monitor value.

In the second I optical receiver 65a2 constituting the first light receiving unit 65a, an anode electrode is connected to the first output end, and a cathode electrode is connected to the ground node.

In the first Q optical receiver 65b1 constituting the second light receiving unit 65b, an anode electrode is connected to the power supply potential node for the light receiving unit, and a cathode electrode is connected to a second output end of the optical monitor 6 that outputs the second monitor value.

In the second Q optical receiver 65b2 constituting the second light receiving unit 65b, an anode electrode is connected to the second output end, and a cathode electrode is connected to the ground node.

Each of the first I optical receiver 65a1 and the second I optical receiver 65a2 and the first Q optical receiver 65b1 and the second Q optical receiver 65b2 is a waveguide optical receiver or a surface incident optical receiver, and in this example, a photodiode which is a SiGe optical receiver is used.

A relationship among the semiconductor laser 5, the optical monitor 6, the temperature adjuster 2, and the lead pins P1 to P6 will be described.

The lead pin P1 is a main signal lead pin for the semiconductor laser 5.

The lead pin P2 is a first monitor lead pin for the optical monitor 6 connected to the first output end of the optical monitor 6.

The lead pin P3 is a second monitor lead pin for the optical monitor 6 connected to the second output end of the optical monitor 6.

The lead pins P4 and P5 are a pair of temperature control lead pins for the temperature adjuster 2.

The lead pin P6 is a power supply pin for supplying power to the first light receiving unit 65a and the second light receiving unit 65b, and is connected to the anode electrode of the first I optical receiver 65a1 and the anode electrode of the first Q optical receiver 65b1. The lead pin P6 is a power supply lead pin for the optical receiver, and also serves as a power supply potential node for the light receiving unit.

The lead pin P7 is a grounding lead pin.

The optical module according the third embodiment only needs to include a total of seven lead pins including six signal lead pins P1 to P6 for respective components and one grounding lead pin P7, and the optical module can be constituted by a small number of lead pins.

As a result, a standard CAN package having a diameter of 5.6 mm, in which the number of lead pins is limited to 7, can be used, and downsizing can be achieved.

Next, an operation of the optical module according to the third embodiment will be described.

A preliminary preparation for operating the optical module acquires the target value ILD_target of the driving photocurrent supplied to the semiconductor laser 5, the target value ITEC_target of the photocurrent supplied to the temperature adjuster 2, the target value Ip_target of the optical power monitor value Ip, and the target value Iλ_target of the wavelength monitor value Iλ/Ip when the wavelength λLD is set as the target value λ_target, similarly to the preliminary preparation of the optical module according to the first and second embodiments.

When the optical module is activated, the driving photocurrent of the target value ILD_target is supplied to the semiconductor laser 5 similarly to the operation of the optical module according to the first embodiment and the second embodiment (step ST2).

When the driving photocurrent of the target value ILD_target is supplied, the semiconductor laser 5 emits the forward laser beam Lf to the outside of the cap 7 through the window 8, and emits the backward laser beam Lb to the first optical coupler 61a and the second optical coupler 61b in the optical monitor 6.

The laser beam from the first optical coupler 61a that has received the backward laser beam Lb of the semiconductor laser 5 is incident on the first optical waveguide 62a by the silicon waveguide constituting the input-side optical multiplexer-demultiplexer 62 from the first port of the input-side optical multiplexer-demultiplexer 62.

On the other hand, the laser beam from the second optical coupler 61b that has received the backward laser beam Lb of the semiconductor laser 5 enters the second optical waveguide 62b constituting the input-side optical multiplexer-demultiplexer 62 from the third port of the input-side optical multiplexer-demultiplexer 62.

The laser beam from the first optical coupler 61a and the laser beam from the second optical coupler 61b incident on the input-side optical multiplexer-demultiplexer 62 are demultiplexed and interfered by the input-side optical multiplexer-demultiplexer 62, and propagated from the second port of the input-side optical multiplexer-demultiplexer 62 to the first asymmetric arm 63a and from the fourth port of the input-side optical multiplexer-demultiplexer 62 to the second asymmetric arm 63b.

The laser beam propagated through the first asymmetric arm 63a is incident as first incident light on the first input node of the 90-degree hybrid configuration optical circuit OC.

The laser beam propagated through the second asymmetric arm 63b is input as second incident light to the second input node of the 90-degree hybrid configuration optical circuit OC.

In the 90-degree hybrid configuration optical circuit OC, the first incident light input to the first input node is demultiplexed into a first split light and a second split light by the first 1×2 optical multiplexer-demultiplexer 67a, and the second incident light input to the second input node is demultiplexed into a third split light and a fourth split light by the second 1×2 optical multiplexer-demultiplexer 67b.

The first split light enters the fifth optical waveguide constituting the first 2×2 optical multiplexer-demultiplexer 68a from the first port of the first 2×2 optical multiplexer-demultiplexer 68a.

On the other hand, the third split light is incident from the third port of the first 2×2 optical multiplexer-demultiplexer 68a into the sixth optical waveguide constituting the first 2×2 optical multiplexer-demultiplexer 68a.

Each of the first split light and the third split light incident on the first 2×2 optical multiplexer-demultiplexer 68a is demultiplexed and interfered by the first 2×2 optical multiplexer-demultiplexer 68a, emitted as the first I output light from the second port of the first 2×2 optical multiplexer-demultiplexer 68a to the first I optical receiver 65a1 constituting the first light receiving unit 65a, and emitted as the second I output light from the fourth port of the first 2×2 optical multiplexer-demultiplexer 68a to the second I optical receiver 65a2 constituting the first light receiving unit 65a.

The first I output light is photoelectrically converted by the first I optical receiver 65a1, the second I output light is photoelectrically converted by the second I optical receiver 65a2, the photocurrent flows through the first I optical receiver 65a1 and the second I optical receiver 65a2, and the I signal illustrated in FIG. 16 appears at the first output end that is the connection point between the first I optical receiver 65a1 and the second I optical receiver 65a2.

The I signal is the first monitor value indicating an analog photocurrent, and is input to the control unit 9.

The second split light enters the seventh optical waveguide constituting the second 2×2 optical multiplexer-demultiplexer 68b from the first port of the second 2×2 optical multiplexer-demultiplexer 68b.

On the other hand, the fourth split light is delayed by 90 degrees by the 90-degree delayer 69 and enters the eighth optical waveguide constituting the second 2×2 optical multiplexer-demultiplexer 68b from the third port of the second 2×2 optical multiplexer-demultiplexer 68b.

Each of the second split light incident on the second 2×2 optical multiplexer-demultiplexer 68b and the fourth split light delayed by 90 degrees is demultiplexed and interfered by the second 2×2 optical multiplexer-demultiplexer 68b, emitted as the first Q output light from the second port of the second 2×2 optical multiplexer-demultiplexer 68b to the first Q optical receiver 65b1 constituting the second light receiving unit 65b, and emitted as the second Q output light from the fourth port of the second 2×2 optical multiplexer-demultiplexer 68b to the second Q optical receiver 65b2 constituting the second light receiving unit 65b.

The phase of the first split light to the third split light is not changed, and the phase of the fourth split light is delayed by 90 degrees, that is, changed by 90 degrees by the 90-degree delayer 69.

The first Q output light is photoelectrically converted by the first Q optical receiver 65b1, the second Q output light is photoelectrically converted by the second Q optical receiver 65b2, a photocurrent flows through the first Q optical receiver 65b1 and the second Q optical receiver 65b2, and the Q signal illustrated in FIG. 16 appears at the first output end that is a connection point between the first Q optical receiver 65b1 and the second Q optical receiver 65b2.

The Q signal has a phase change of 90 degrees with respect to the I signal.

The Q signal has a phase change of 90 degrees with respect to the I signal, is a second monitor value indicating an analog photocurrent, and is input to the control unit 9.

As illustrated in FIG. 16, a constellation can be mapped on an IQ plane based

on the I signal that is an analog photocurrent indicating the first monitor value and the Q signal that is an analog photocurrent indicating the second monitor value.

In the constellation map illustrated in FIG. 16, the I axis indicates the magnitude of the I signal, that is, the value of the analog photocurrent indicating the first monitor value, and the Q axis indicates the magnitude of the Q signal, that is, the value of the analog photocurrent indicating the second monitor value.

If the optical power of the backward laser beam Lb of the semiconductor laser 5 is constant, the constellation goes around a circumference having a constant radius corresponding to the optical power according to a change in the wavelength of the backward laser beam Lb.

As the optical power increases, the radius of the circle increases, and as the optical power decreases, the radius of the circle decreases.

Therefore, the optical power monitor value Ip can be obtained by knowing the position of the constellation based on the first monitor value and the second monitor value from the center on the constellation map.

On the other hand, when the wavelength of the backward laser beam Lb of the semiconductor laser 5 changes, the angle of the radius of curvature formed by the constellation changes.

Therefore, the wavelength monitor value Iλ can be obtained by knowing the angle of the line segment connecting the center on the constellation map and the position of the constellation based on the first monitor value and the second monitor value with respect to the I axis.

The wavelength monitor value Iλ/Ip can be obtained by obtaining the optical power monitor value Ip and the wavelength monitor value Iλ (step ST3a).

That is, since the change in wavelength of the backward laser beam Lb is proportional to the rotation of the constellation, the change in wavelength of the backward laser beam Lb can be seamlessly observed, and it is not necessary to separately perform phase adjustment on the optical monitor 6.

The control unit 9 converts the first monitor value by a photocurrent into a voltage, further converts analog to digital, sets the first monitor value as digital information, converts the second monitor value based on a photocurrent into a voltage, further converts analog to digital, sets the second monitor value as digital information, and compares the first and second monitor values with the constellation map obtained in advance and stored in the storage unit to obtain an optical power monitor value Ip, a wavelength monitor value Iλ, and a wavelength monitor value Iλ/Ip.

In the operation after obtaining the optical power monitor value Ip, the wavelength monitor value Iλ, and the wavelength monitor value Iλ/Ip, similarly to the operation of the optical module according to the first embodiment and the second embodiment, the control unit 9 performs the operation after step ST4 to adjust the temperature of the semiconductor laser and adjust the light output from the semiconductor laser and the oscillation wavelength.

As described above, similarly to the optical modules according to the first and second embodiments, the optical module according to the third embodiment can be controlled to have a precise single wavelength with respect to the laser beam from the semiconductor laser 5, the number of parts is small, and downsizing can be achieved.

In the optical module according to the third embodiment, similarly to the optical module according to the second embodiment, in the optical monitor 6, the wavelength monitor value Iλ/Ip obtained from the first monitor value obtained from the first light receiving unit 65a and the second monitor value obtained from the second light receiving unit 65b can be a wavelength monitor value having no temperature dependence.

Furthermore, the optical module according to the third embodiment can obtain the optical power monitor value Ip, the wavelength monitor value Iλ, and the wavelength monitor value Iλ/Ip with high accuracy without separately performing phase adjustment on the optical monitor 6.

In the optical module according to the third embodiment, similarly to the optical module according to the second embodiment, the first asymmetric arm 63a includes the silicon nitride waveguides 63a1 and 63a2 and the silicon waveguide 63a3, and the second asymmetric arm 63b includes the silicon waveguides 63b1 to 63b3 and the silicon nitride waveguides 63b4 and 63b5, but similarly to the optical module according to the first embodiment, each of the first asymmetric arm 63a and the second asymmetric arm 63b may include a single silicon waveguide.

The optical module according to the third embodiment is not limited to a planar waveguide optical monitor using a silicon photonics chip, and may be a planar waveguide optical monitor using an indium phosphorus substrate which is a compound semiconductor or a glass substrate.

Note that free combinations of the individual embodiments, modifications of any components of the individual embodiments, or omissions of any components in the individual embodiments are possible.

### Industrial Applicability

The optical module according to the present disclosure is preferable for an optical module used in a large-capacity optical communication system, particularly, an optical module used in a digital coherent communication method.

### REFERENCE SIGNS LIST

1: stem, 2: temperature adjuster, 3: base, 4: submount for semiconductor laser, 5: semiconductor laser, 6: optical monitor (planar waveguide optical monitor), 61a: first optical coupler, 61b: second optical coupler, 62: input-side optical multiplexer-demultiplexer, 63a: first asymmetric arm, 63b: second asymmetric arm, 64: output-side optical multiplexer-demultiplexer, 65a: first optical receiver, 65b: second optical receiver, 66: phase adjuster, 7: cap, 8: window, 9: control unit, 10: package, P1 to P7: lead pin

1. An optical module comprising: a semiconductor laser; and an optical monitor to receive a laser beam from the semiconductor laser and output a first monitor value and a second monitor value for estimating intensity and a wavelength of the laser beam from the semiconductor laser, wherein
the optical monitor constitutes an optical interferometer including a first optical coupler to receive the laser beam from the semiconductor laser, a second optical coupler to receive the laser beam from the semiconductor laser, a first optical receiver to output the first monitor value, and a second optical receiver to output the second monitor value, and a first path from the first optical coupler to the first optical receiver and a second path from the second optical coupler to the second optical receiver are asymmetric.

2. The optical module according to claim 1, wherein
the optical interferometer in the optical monitor includes:
an input-side optical multiplexer-demultiplexer having a first port to a fourth port, with the first port coupled to the first optical coupler and the third port coupled to the second optical coupler;
a first asymmetric arm including an optical waveguide in which an input node is optically connected to the second port of the input-side optical multiplexer-demultiplexer;
a second asymmetric arm including an optical waveguide in which an input node is optically connected to the fourth port of the input-side optical multiplexer-demultiplexer, and a physical length of the optical waveguide is different from a physical length of the optical waveguide included in the first asymmetric arm; and
an output-side optical multiplexer-demultiplexer having a first port to a fourth port, with the first port optically connected to an output node of the first asymmetric arm, the third port optically connected to an output node of the second asymmetric arm, the second port coupled to the first optical receiver, and the fourth port coupled to the second optical receiver, wherein
the first path is a propagation path of light from the first port of the input-side optical multiplexer-demultiplexer to the second port of the output-side optical multiplexer-demultiplexer via the input-side optical multiplexer-demultiplexer, the first asymmetric arm, and the output-side optical multiplexer-demultiplexer, and
the second path is a propagation path of light from the second port of the input-side optical multiplexer-demultiplexer to the fourth port of the output-side optical multiplexer-demultiplexer via the input-side optical multiplexer-demultiplexer, the second asymmetric arm, and the output-side optical multiplexer-demultiplexer.

3. An optical module comprising:
a semiconductor laser; and an optical monitor to receive a laser beam from the semiconductor laser and output a first monitor value and a second monitor value for estimating intensity and a wavelength of the laser beam from the semiconductor laser, wherein
the optical monitor includes
a first optical coupler to receive the laser beam from the semiconductor laser, a second optical coupler to receive the laser beam from the semiconductor laser, a first optical receiver to output the first monitor value, a second optical receiver to output the second monitor value, and an optical interferometer,
the optical interferometer includes:
an input-side optical multiplexer-demultiplexer having a first port to a fourth port, with the first port coupled to the first optical coupler and the third port coupled to the second optical coupler;
a first asymmetric arm including an optical waveguide in which an input node is optically connected to the second port of the input-side optical multiplexer-demultiplexer;
a second asymmetric arm including an optical waveguide in which an input node is optically connected to the fourth port of the input-side optical multiplexer-demultiplexer, and having a physical length of the optical waveguide different from a physical length of the optical waveguide included in the first asymmetric arm; and
an optical circuit having a first input node, a second input node, a first output node, and a second output node, with the first input node optically connected to an output node of the first asymmetric arm, the second input node optically connected to an output node of the second asymmetric arm, the first output node optically connected to the first optical receiver, and the second output node optically connected to the second optical receiver, the optical circuit constituting an interference measurement system for viewing wavelength dependence by the first optical receiver and the second optical receiver.

4. The optical module according to claim 3, wherein
the optical waveguide in the first asymmetric arm has a common portion and a non-common portion, the optical waveguide in the non-common portion is an optical waveguide having a first group refractive index, and
the optical waveguide in the second asymmetric arm has a common portion and a non-common portion, and the optical waveguide of the non-common portion is an optical waveguide having a second group refractive index having temperature dependence of a group refractive index different from the first group refractive index.

5. An optical module comprising:
a semiconductor laser; and an optical monitor to receive a laser beam from the semiconductor laser and output a first monitor value and a second monitor value for estimating intensity and a wavelength of the laser beam from the semiconductor laser, wherein
the optical monitor includes
a first optical coupler to receive the laser beam from the semiconductor laser, a second optical coupler to receive the laser beam from the semiconductor laser, a first optical receiver to output the first monitor value, a second optical receiver to output the second monitor value, and an optical interferometer,
the optical interferometer includes:
an input-side optical multiplexer-demultiplexer having a first port to a fourth port, with the first port coupled to the first optical coupler and the third port coupled to the second optical coupler;
a first asymmetric arm in which an input node is optically connected to the second port of the input-side optical multiplexer-demultiplexer, the first asymmetric arm including an optical waveguide of a common portion and an optical waveguide of a non-common portion, the optical waveguide of the non-common portion being an optical waveguide having a first group refractive index;
a second asymmetric arm in which an input node is optically connected to the fourth port of the input-side optical multiplexer-demultiplexer, the second asymmetric arm including an optical waveguide of a common portion and an optical waveguide of a non-common portion, the optical waveguide of the non-common portion being an optical waveguide having a second group refractive index having temperature dependence of a group refractive index different from the first group refractive index, a physical length of the non-common portion being different from a physical length of the optical waveguide of the non-common portion in the first asymmetric arm; and
an optical circuit having a first input node, a second input node, a first output node, and a second output node, with the first input node optically connected to an output node of the first asymmetric arm, the second input node optically connected to an output node of the second asymmetric arm, the first output node optically connected to the first optical receiver, and the second output node optically connected to the second optical receiver, the optical circuit constituting an interference measurement system for viewing wavelength dependence by the first optical receiver and the second optical receiver.

6. The optical module according to claim 3, wherein the optical circuit constituting the interference measurement system includes a first port to a fourth port, the first port is the first input node of the optical circuit, the second port is the first output node of the optical circuit, the third port is the second input node of the optical circuit, and the fourth port is an output-side optical multiplexer-demultiplexer that is the second output node of the optical circuit.

7. The optical module according to claim 6, wherein
the input-side optical multiplexer-demultiplexer is an optical multiplexer-demultiplexer having a power branch ratio of 2:8, and
the output-side optical multiplexer-demultiplexer is an optical multiplexer-demultiplexer having a power branch ratio of 2:8.

8. The optical module according to claim 6, wherein
a maximum value of a gradient variation amount indicating a tolerance for wavelength dependence of a photocurrent indicating a first monitor value output from the first optical receiver and a photocurrent indicating a second monitor value output from the second optical receiver is within 30% within a range of an assumed mounting deviation in a coupling light beam of the first optical coupler and the second optical coupler and the input-side optical multiplexer-demultiplexer.

9. The optical module according to claim 6, wherein
an oscillation wavelength from the semiconductor laser is equal to or less than 0.1 nm within a temperature change range in which a shift amount in a wavelength direction of wavelength dependence of a wavelength monitor value, which is a ratio between an optical power monitor value calculated from a photocurrent indicating a first monitor value output from the first optical receiver and a photocurrent indicating a second monitor value output from the second optical receiver and a wavelength monitor value, is 100 degrees.

10. The optical module according to claim 6, wherein
the optical monitor is a planar waveguide optical monitor using a silicon photonics chip formed by integrating the first optical coupler, the second optical coupler, the input-side optical multiplexer-demultiplexer, the first asymmetric arm, the second asymmetric arm, the output-side optical multiplexer-demultiplexer, the first optical receiver, and the second optical receiver on a flat surface of a silicon substrate, and
each of the first optical coupler and the second optical coupler is a grating coupler.

11. The optical module according to claim 5, wherein
the optical circuit constituting the interference measurement system includes a first port to a fourth port, the first port is the first input node of the optical circuit, the second port is the first output node of the optical circuit, the third port is the second input node of the optical circuit, and the fourth port is an output-side optical multiplexer-demultiplexer that is the second output node of the optical circuit,
the optical monitor is a planar waveguide optical monitor formed by integrating the first optical coupler, the second optical coupler, the input-side optical multiplexer-demultiplexer, the first asymmetric arm, the second asymmetric arm, the output-side optical multiplexer-demultiplexer, the first optical receiver, and the second optical receiver, and
the physical length of the optical waveguide of the non-common portion in the first asymmetric arm is denoted by (L+ΔL), the group refractive index is denoted by n₂, a physical length of an optical waveguide of the second asymmetric arm is denoted by L, a group refractive index is denoted by n₁, a linear expansion coefficient of a substrate in a planar waveguide optical monitor is denoted by α, dn₁/dT+n₁α>dn₂/dT+n₂α is satisfied, a phase difference θ between a photocurrent from the first optical receiver and a photocurrent from the second optical receiver is expressed by n₂(L+ΔL)−n₁·L=(λ/2π)·θ, and a physical length L is obtained by a following expression in such a manner that a temperature derivative of the expression is always 0.
$$L = {( \frac{\frac{{dn}_{1}}{dT} + {n}_{1} α}{\frac{{dn}_{2}}{dT} + {n}_{2} α} - 1 )}^{- 1} \cdot Δ L$$

12. The optical module according to claim 3, further comprising: a temperature adjuster to adjust a temperature in the semiconductor laser and a temperature in the optical monitor, and perform control to change a temperature to be given to the semiconductor laser and the optical monitor when a wavelength monitor value Iλ/Ip, which is a ratio between an optical power monitor value Ip that is a total value of the first monitor value and the second monitor value and a wavelength monitor value Iλ that is a difference value between the first monitor value and the second monitor value, deviates from a wavelength set value.

13. The optical module according to claim 12, further comprising:
a stem on which the temperature adjuster is mounted;
a base that is mounted and fixed on a mounting surface of the temperature adjuster and includes an elevation surface portion on which the semiconductor laser is mounted and fixed, and a flat surface portion that is formed integrally with the elevation surface portion and on which the optical monitor is mounted and fixed at a position where a backward laser beam of the semiconductor laser is received; and
a tubular cap with one side open, the tubular cap having a bottomed portion and a side wall portion, the bottomed portion having a window through which a forward laser beam of the semiconductor laser is emitted, the cap covering an inner flat surface side of the stem, and having an open end surface of the side wall portion fixed in contact with a peripheral end portion of an inner flat surface of the stem.

14. The optical module according to claim 13, further comprising:
a main signal lead pin penetrating the stem and having an inner lead portion exposed from the inner flat surface of the stem to which an electrode of the semiconductor laser is connected;
a first monitor lead pin penetrating the stem and having an inner lead portion exposed from the inner flat surface of the stem to which the first optical receiver of the optical monitor is connected;
a second monitor lead pin penetrating the stem and having an inner lead portion exposed from the inner flat surface of the stem to which the second optical receiver of the optical monitor is connected; and
a pair of temperature control lead pins penetrating the stem and having an inner lead portion exposed from the inner flat surface of the stem to which a pair of electrodes in the temperature adjuster is connected.

15. The optical module according to claim 3, wherein
the optical circuit constituting the interference measurement system is a 90-degree hybrid configuration optical circuit to receive an optical output from the first asymmetric arm to the first input node, receive an optical output of the second asymmetric arm to the second input node, output an I optical output to the first output node, and output a Q optical output to the second output node,
the first optical receiver receives an I optical output from the 90-degree hybrid configuration optical circuit and outputs the first monitor value that is an I signal, and
the second optical receiver receives a Q optical output from the 90-degree hybrid configuration optical circuit and outputs the second monitor value that is a Q signal.

16. The optical module according to claim 15, wherein
the first optical receiver includes a first I optical receiver and a second I optical receiver connected in series, and outputs the first monitor value to a connection point between the first I optical receiver and the second I optical receiver,
the second optical receiver includes a first Q optical receiver and a second Q optical receiver connected in series, and outputs the second monitor value to a connection point between the first Q optical receiver and the second Q optical receiver, and
the 90-degree hybrid configuration optical circuit includes:
a first 1×2 optical multiplexer-demultiplexer having a first port to a third port, with the first port optically connected to an output node of the first asymmetric arm; and
a second 1×2 optical multiplexer-demultiplexer having a first port to a third port, with the first port optically connected to an output node of the second asymmetric arm;
a 90-degree delayer having an input node optically connected to a third port of the second 1×2 optical multiplexer-demultiplexer;
a first 2×2 optical multiplexer-demultiplexer having a first port to a fourth port, in which the first port is optically connected to a second port of the first 1×2 optical multiplexer-demultiplexer, the third port is optically connected to a second port of the second 1×2 optical multiplexer-demultiplexer, the first 2×2 optical multiplexer-demultiplexer outputs first I output light from the third port to the first I optical receiver, and outputs second I output light from the fourth port to the second I optical receiver; and
a second 2×2 optical multiplexer-demultiplexer having a first port to a fourth port, in which the first port is optically connected to a third port of the second 1×2 optical multiplexer-demultiplexer, the third port is optically connected to an output node of the 90-degree delayer, and outputs first Q output light from the third port to the first Q optical receiver and outputs second Q output light from the fourth port to the second Q optical receiver, and
the I optical output includes the first I output light and the second I output light, and the Q optical output includes the first Q output light and the second Q output light.

17. The optical module according to claim 5, wherein
the optical circuit constituting the interference measurement system is a 90-degree hybrid configuration optical circuit to receive an optical output from the first asymmetric arm to the first input node, receive an optical output of the second asymmetric arm to the second input node, output an I optical output to the first output node, and output a Q optical output to the second output node,
the first optical receiver receives an I optical output from the 90-degree hybrid configuration optical circuit and outputs the first monitor value that is an I signal,
the second optical receiver receives a Q optical output from the 90-degree hybrid configuration optical circuit and outputs the second monitor value that is a Q signal,
the optical monitor is a planar waveguide optical monitor in which the first optical coupler, the second optical coupler, the input-side optical multiplexer-demultiplexer, the first asymmetric arm, the second asymmetric arm, the 90-degree hybrid configuration optical circuit, the first optical receiver, and the second optical receiver are integrated, and
the physical length of the optical waveguide of the non-common portion in the first asymmetric arm is denoted by (L+ΔL), the group refractive index is denoted by n₂, a physical length of an optical waveguide of the second asymmetric arm is denoted by L, a group refractive index is denoted by n₁, a linear expansion coefficient of a substrate in a planar waveguide optical monitor is denoted by α, dn₁/dT+n₁α>dn₂/dT+n₂α is satisfied, a phase difference θ between a photocurrent from the first optical receiver and a photocurrent from the second optical receiver is expressed by n₂(L+ΔL)−n₁·L=(λ/2π)·θ, and a physical length Lis obtained by a following expression in such a manner that a temperature derivative of the expression is always 0.
$$L = {( \frac{\frac{{dn}_{1}}{dT} + {n}_{1} α}{\frac{{dn}_{2}}{dT} + {n}_{2} α} - 1 )}^{- 1} \cdot Δ L$$

18. The optical module according to claim 15, further comprising: a temperature adjuster to adjust a temperature in the semiconductor laser and a temperature in the optical monitor, and perform control to change a temperature to be given to the semiconductor laser and the optical monitor when a wavelength monitor value Iλ/Ip, which is a ratio between an optical power monitor value Ip and a wavelength monitor value Iλ obtained by a constellation mapped on an IQ plane by an I signal indicated by the first monitor value and a Q signal indicated by the second monitor value, deviates from a wavelength set value.

19. The optical module according to claim 15, further comprising:
a first I optical receiver and a second I optical receiver in the first optical receiver, connected in series between a power supply potential node for the light receiver and a grounding node,
a first Q optical receiver and a second Q optical receiver in the second optical receiver, connected in series between a power supply potential node for the light receiver and a grounding node,
a temperature adjuster to adjust a temperature in the semiconductor laser and a temperature in the optical monitor, and perform control to change a temperature to be given to the semiconductor laser and the optical monitor when a wavelength monitor value Iλ/Ip, which is a ratio between an optical power monitor value Ip and a wavelength monitor value Iλ obtained by a constellation mapped on an IQ plane by an I signal indicated by the first monitor value and a Q signal indicated by the second monitor value, deviates from a wavelength set value;
a stem on which the temperature adjuster is placed;
a base that is mounted and fixed on a mounting surface of the temperature adjuster and includes an elevation surface portion on which the semiconductor laser is mounted and fixed, and a flat surface portion that is formed integrally with the elevation surface portion and on which the optical monitor is mounted and fixed at a position where a backward laser beam of the semiconductor laser is received;
a tubular cap with one side open, the tubular cap having a bottomed portion and a side wall portion, the bottomed portion having a window through which a forward laser beam of the semiconductor laser is emitted, the cap covering an inner flat surface side of the stem, and having an open end surface of the side wall portion fixed in contact with a peripheral end portion of an inner flat surface of the stem;
a main signal lead pin penetrating the stem and having an inner lead portion exposed from the inner flat surface of the stem to which an electrode of the semiconductor laser is connected;
a first monitor lead pin penetrating the stem and having an inner lead portion exposed from the inner flat surface of the stem to which a connection point between the first I optical receiver and the second I optical receiver is connected;
a second monitor lead pin penetrating the stem and having an inner lead portion exposed from the inner flat surface of the stem to which a connection point between the first Q optical receiver and the second Q optical receiver is connected;
a pair of temperature control lead pins penetrating the stem and having an inner lead portion exposed from the inner flat surface of the stem to which a pair of electrodes in the temperature adjuster is connected; and
a power supply lead pin for an optical receiver to which a power supply side electrode of a first I optical receiver located on a power supply side in the first optical receiver and a power supply side electrode of a first Q optical receiver located on a power supply side in the second optical receiver are connected.

20. A method of controlling an optical module comprising: a semiconductor laser; an optical monitor to receive a laser beam from the semiconductor laser and output a first monitor value and a second monitor value for estimating intensity and a wavelength of the laser beam from the semiconductor laser; and a temperature adjuster to adjust a temperature in the semiconductor laser and a temperature in the optical monitor, wherein the optical monitor includes a first optical coupler to receive the laser beam from the semiconductor laser, a second optical coupler to receive the laser beam from the semiconductor laser, a first optical receiver to output the first monitor value, and a second optical receiver to output the second monitor value, and a first path from the first optical coupler to the first optical receiver and a second path from the second optical coupler to the second optical receiver are asymmetric, the method comprising:
adjusting a temperature to be given to the semiconductor laser and the optical monitor by the temperature adjuster when a wavelength monitor value Iλ/Ip, which is a ratio between an optical power monitor value Ip that is a total value of the first monitor value and the second monitor value and a wavelength monitor value Iλ that is a difference value between the first monitor value and the second monitor value, deviates from a wavelength set value.
